(19) United States
(12) Patent Application Publication
(10) Pub. No.: US 2026/0129843 A1
(43) Pub. Date: May 7, 2026

(54) DIGIT LINE FORMATION IN VERTICAL THREE-DIMENSIONAL (3D) MEMORY

(71) Applicant: Micron Technology, Inc., Boise, ID (US)

(72) Inventors: Gautham Muthusamy, Meridian, ID (US); Hisham Abdussamad Abbas, Meridian, ID (US); Xiaohui Zhao, Boise, ID (US); John F. Kaeding, Boise, ID (US); Yuanzhi Ma, Boise, ID (US); Ting Zhao, Boise, ID (US); Albert Liao, Boise, ID (US); S. M. Istiaque Hossain, Boise, ID (US); Scott E. Sills, Boise, ID (US); Durai Vishak Nirmal Ramaswamy, Boise, ID (US); Antik Mallick, Boise, ID (US)

(21) Appl. No.: 19/369,879

(22) Filed: Oct. 27, 2025

Related U.S. Application Data
(60) Provisional application No. 63/715,858, filed on Nov. 4, 2024.

(51) Int. Cl. H10B 12/00; H10D 30/00; H10D 30/01; H10D 62/10; H10D 62/832

(52) U.S. Cl. CPC H10B 12/482; H10B 12/05; H10B 12/488; H10D 30/0191; H10D 30/502; H10D 62/121; H10D 62/832

(57) ABSTRACT

Systems, methods and apparatus are provided for an array of vertically stacked memory cells having horizontally oriented access devices and storage nodes. The horizontally oriented access devices having a first source/drain regions and a second source/drain regions separated by channel regions. Gates at the channel regions formed fully around every surface of the channel region as gate-all-around (GAA) structures separated from channel regions by gate dielectrics. The memory cells have horizontally oriented storage nodes connected to the second source/drain regions and digit lines connected to the first source/drain regions.

### PRIORITY INFORMATION

This application claims the benefit of U.S. Provisional Application Number 63/715,858, filed on Nov. 4, 2024, the contents of which are incorporated herein by reference.

### TECHNICAL FIELD

The present disclosure relates generally to memory devices, and more particularly, to digit line formation in vertical three-dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain regions separated by epitaxially grown channel regions. A gate may oppose the channel region and be separated therefrom by a gate dielectric. An access line, such as a word line, is electrically connected to the gate of the DRAM cell. A DRAM cell can include a storage node, such as a capacitor cell, connected by the access device to a digit line. The access device can be activated (e.g., to select the cell) by an access line connected to the access transistor. The capacitor can store a charge corresponding to a data value of a respective cell (e.g., a logic “1” or “0”).

### BRIEF DESCRIPTION OF THE DRAWINGS

FIG. 1A is a schematic illustration of a horizontal access device in a vertical three-dimensional (3D) memory in accordance with a number of embodiments of the present disclosure.

FIG. 1B is a perspective view illustrating a portion of a horizontal access device in vertical three-dimensional (3D) memory in accordance with a number of embodiments of the present disclosure.

FIG. 2 illustrates a portion of a horizontal access device in vertical three-dimensional (3D) memory in accordance with a number of embodiments of the present disclosure.

FIG. 3 illustrates a portion of a vertical 3D memory array in accordance with a number of embodiments of the present disclosure.

FIG. 4 is a cross-sectional view, at one stage of a semiconductor fabrication process, for digit line formation in vertical three-dimensional (3D) memory in accordance with a number of embodiments of the present disclosure.

FIGS. 5A to 5B illustrate an example method, at one stage of a semiconductor fabrication process, for digit line formation in vertical three-dimensional (3D) memory, in accordance with a number of embodiments of the present disclosure.

FIGS. 6A to 6C illustrate an example method, at another stage of a semiconductor fabrication process, for digit line formation in vertical three-dimensional (3D) memory, in accordance with a number of embodiments of the present disclosure.

FIGS. 7A to 7C illustrate an example method, at another stage of a semiconductor fabrication process, for digit line formation in vertical three-dimensional (3D) memory, in accordance with a number of embodiments of the present disclosure.

FIGS. 8A to 8C illustrate an example method, at another stage of a semiconductor fabrication process, for digit line formation in vertical three-dimensional (3D) memory, in accordance with a number of embodiments of the present disclosure.

FIGS. 9A to 9C illustrate epitaxially growing Si material to form enlarged epitaxially grown Si material contacts, at another stage of a semiconductor fabrication process, for digit line formation in vertical three-dimensional (3D) memory, in accordance with a number of embodiments of the present disclosure.

FIGS. 10A to 10B illustrate forming a plurality of spaced vertical columns having a plurality of spaced vertical openings therebetween, at another stage of a semiconductor fabrication process, for digit line formation in vertical three-dimensional (3D) memory, in accordance with a number of embodiments of the present disclosure.

FIG. 11 illustrates forming the plurality of spaced vertical openings, at another stage of a semiconductor fabrication process, for digit line formation in vertical three-dimensional (3D) memory, in accordance with a number of embodiments of the present disclosure.

FIG. 12 illustrates forming a plurality of spaced, multi-layer vertical digit lines, at another stage of a semiconductor fabrication process, for digit line formation in vertical three-dimensional (3D) memory, in accordance with a number of embodiments of the present disclosure.

FIG. 13 illustrates forming the plurality of spaced, multi-layer vertical digit lines, at another stage of a semiconductor fabrication process, for digit line formation in vertical three-dimensional (3D) memory, in accordance with a number of embodiments of the present disclosure.

FIG. 14 is a block diagram of an apparatus in the form of a computing system including a memory device in accordance with a number of embodiments of the present disclosure.

### DETAILED DESCRIPTION

Embodiments of the present disclosure describe digit line formation in vertical three-dimensional (3D) memory. A vertically oriented digit line is formed with horizontally oriented access devices and access lines in an array of vertically stacked memory cells. The horizontal access devices are integrated with horizontally oriented access lines having a first source/drain regions and a second source/drain regions separated by channel regions and integrated with vertically oriented digit lines. In vertically stacked memory array structures, such as transistor structures, polycrystalline silicon (also referred to as polysilicon) can be leaky, allowing current to leak through the polycrystalline structure, making the transistor less effective. Single crystal silicon is not very leaky. However, single crystal silicon cannot grow on amorphous dielectric materials, such as oxides or nitrides, which are the common materials upon which transistors are formed.

However, as disclosed in the embodiments of the present disclosure, it is possible to use a silicon wafer for a transistor that can be utilized as a substrate during the high temperature processes required for single crystal silicon formation. In such embodiments, a layer of silicon germanium can be grown on the silicon substrate. Single crystal silicon can, then, be grown on the silicon germanium.

This may be accomplished, for example, by providing a thin single crystal silicon germanium layer, as a seed layer, and then forming the single crystal silicon germanium layer thickness. Once the desired layer thickness is formed, a silicon layer can be formed into the surface of the silicon germanium layer. As with the silicon germanium layer, this may be accomplished, for example, by providing a thin single crystal silicon layer, as a seed layer, and then forming the thin single crystal silicon layer thickness into a thicker single crystal silicon layer.

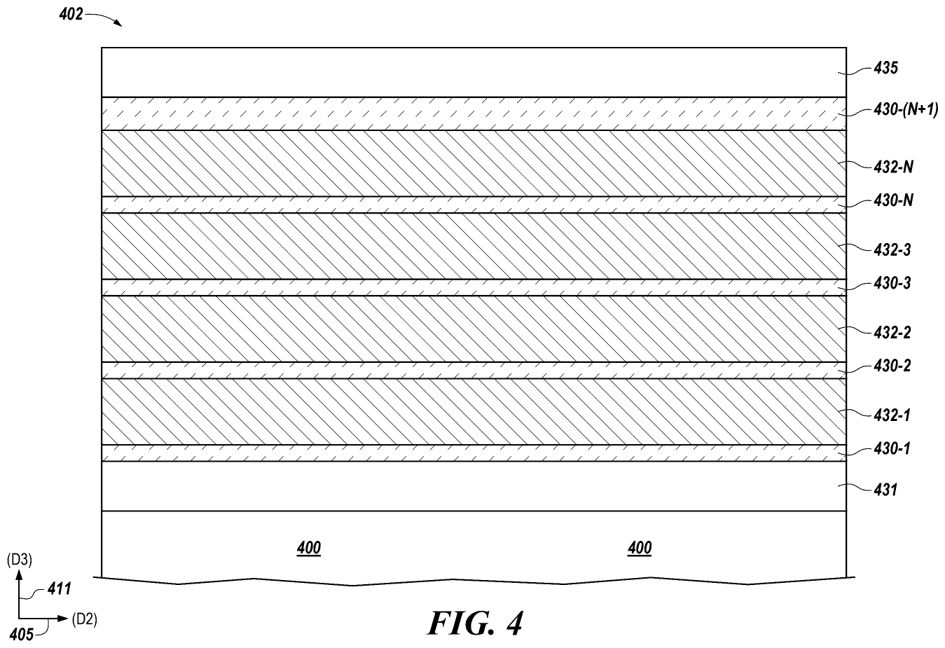

Depending on the silicon germanium concentration, if silicon is x quantity and germanium is y quantity and, if y is smaller than x, then silicon/silicon germanium has a small lattice mismatch with respect to the lattice of single crystal silicon. This allows silicon to be formed on top of silicon germanium with a single crystal structure. If a thin layer of single crystal silicon is applied to the surface of the silicon germanium, then the whole silicon layer acts as a seed for the growth of the single crystal silicon layer. Such layering can be done in alternating iterations (e.g., SiGe/Si/SiGe/Si, etc.) to create a superlattice structure in the form of a vertical stack such as shown in FIG. 4.

For example, a seed layer of silicon germanium can be formed that is 100 Angstroms in thickness (height) and can be grown to, for example 1000 Angstroms. A thin silicon seed layer can be formed on the surface of the silicon germanium layer that is, for example, 50 Angstroms and can be grown to a thickness of, for example, 300 Angstroms. These thicknesses are merely provided as examples and should not be regarded as limiting unless recited explicitly in a particular claim.

The transistor devices of the present disclosure will have better performance with regard to I-on, better I-off, drivability, and/or leakage current because there is no grain boundary and therefore current cannot leak through the grain boundary which is where leakage often occurs in polysilicon. In some embodiments, devices can have, for example, three orders of magnitude lower I-off (leakage).

Advantages to the structure and process described herein can include a lower off-current (Ioff) for the access devices, as compared to silicon based (Si-based) access devices (e.g., transistors), better DRAM refresh requirement, and/or reduced gate/drain induced leakage (GIDL) for the access devices. Combined with a gate all around (GAA) structure at the channel region of the semiconductor material, provides better electrostatic control on the channel, better subthreshold slope and a more cost-effective process.

During formation of the 3D memory array, one step in the semiconductor fabrication process can include forming digit lines. In the process described herein, the digit lines can be vertically oriented in the 3D memory array. The digit lines can be formed in a vertical opening in the 3D memory array to conductively interconnect memory cells along vertical columns.

However, previous approaches have variable a contact junction surface areas between the digit line and a source/drain region. The variability degrades current off and increases the likelihood of an electrical short occurring between digit lines and word lines.

Digit line formation in vertical 3D memory according to the disclosure can allow for increased utilization of contact junction surface area. Epitaxial growth of Si material to form enlarged Si material contacts can provide a larger surface area for contact junctions between digit lines and source/drain regions, improving the current on distribution.

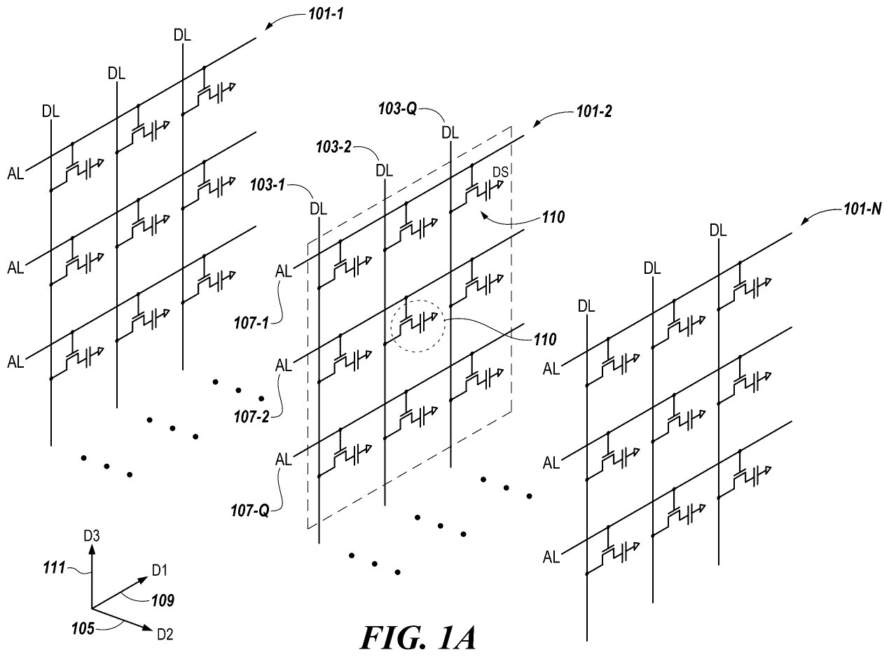

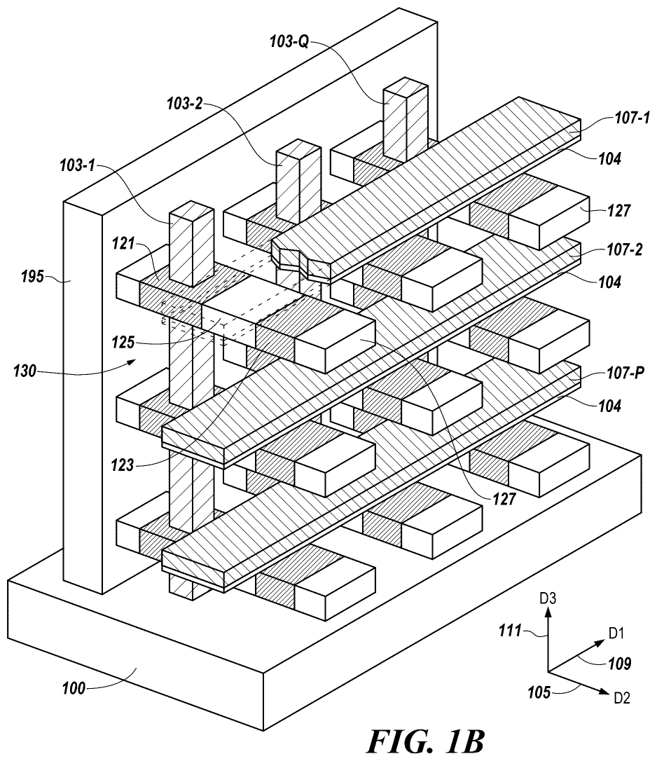

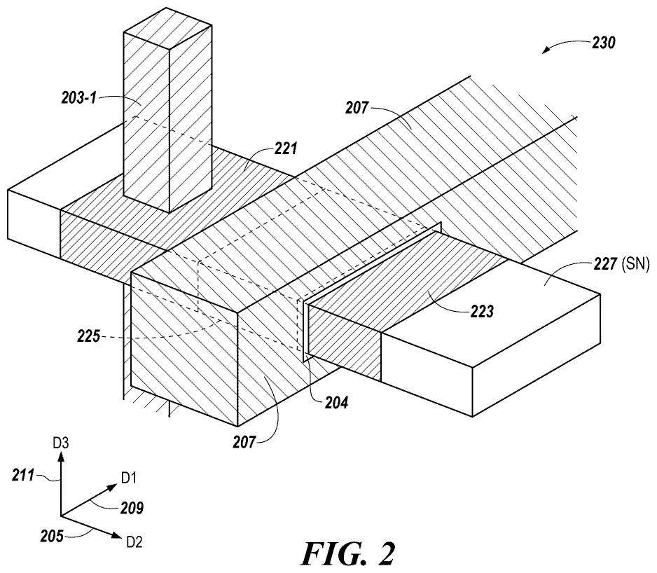

The figures herein follow a numbering convention in which the first digit or digits correspond to the figure number of the drawing and the remaining digits identify an element or component in the drawing. Similar elements or components between different figures may be identified by the use of similar digits. For example, reference numeral 103 may reference element “03” in FIG. 1, and a similar element may be referenced as 203 in FIG. 2. Multiple analogous elements within one figure may be referenced with a reference numeral followed by a hyphen and another numeral or a letter. For example, 302-1 may reference element 302-1 in FIG. 3 and 302-2 may reference element 302-2, which may be analogous to element 302-1. Such analogous elements may be generally referenced without the hyphen and extra numeral or letter. For example, elements 302-1 and 302-2 or other analogous elements may be generally referenced as 302.

FIG. 1A is a schematic illustration of a horizontal access device in a vertical three-dimensional (3D) memory in accordance with a number of embodiments of the present disclosure. FIG. 1A illustrates a circuit diagram showing a cell array of a 3D semiconductor memory device according to embodiments of the present disclosure. FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-P (which also may be referred to as word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1A, the access lines 107-1, 107-2, . . . , 107-P are illustrated extending in a first direction (D1) 109 and the digit lines 103-1, 103-2,. 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., memory cell 110, may include an access device, e.g., access transistor, and a storage node located at an intersection of each access line 107-1, 107-2, . . . , 107-P and each digit line 103-1, 103-2, . . . , 103-Q. Memory cells may be written to, or read from, using the access lines 107-1, 107-2, . . . , 107-P and digit lines 103-1, 103-2, . . . , 103-Q. The access lines 107-1, 107-2, . . . , 107-P may conductively interconnect memory cells along horizontal rows of each sub cell array 101-, 101-2, . . . , 101-N, and the digit lines 103-1, 103-2, . . . , 103-Q may conductively interconnect memory cells along vertical columns of each sub cell array 101-, 101-2, . . . , 101-N. One memory cell, e.g. 110, may be located between one access line, e.g., 107-2, and one digit line, e.g., 103-2. Each memory cell may be uniquely addressed through a combination of an access line 107-1, 107-2, . . . , 107-P and a digit line 103-1, 103-2, . . . , 103-Q.

The access lines 107-1, 107-2, . . . , 107-P may be or include conducting patterns (e.g., metal lines) disposed on and spaced apart from a substrate. The access lines 107-1, 107-2, . . . , 107-P may extend in a first direction (D1) 109. The access lines 107-1, 107-2, . . . , 107-P in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B is a perspective view illustrating a portion of a horizontal access device in vertical three-dimensional (3D) memory, e.g., a portion of a sub cell array 101-2 shown in FIG. 1A as a vertically oriented stack of memory cells in an array, in accordance with a number of embodiments of the present disclosure.

As shown in FIG. 1B, a substrate 100 may have formed thereon one of the plurality of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1), a second level (L2), and a third level (L3). The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 107-1, 107-2, . . . , 107-P connections and digit line 103-1, 103-2, . . . , 103-Q connections. The plurality of discrete components to the horizontally oriented access devices 130, e.g., transistors, may be formed in a plurality of iterations of vertically, repeating layers within each level, as described in more detail below, and may extend horizontally in the second direction (D2) 105, analogous to second direction (D2) 105 shown in FIG. 1A.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . . , 107-P extend in the first direction (D1) 109, analogous to the first direction (D1) 109 in FIG. 1A. The plurality of horizontally oriented access lines 107-1, 107-2, . . . , 107-P may be analogous to the access lines 107-1, 107-2, . . . , 107-P shown in FIG. 1A. The plurality of horizontally oriented access lines 107-1, 107-2, . . . , 107-P may be arranged, e.g., “stacked”, along the third direction (D3) 111. The plurality of horizontally oriented access lines 107-1, 107-2, . . . , 107-P may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1), (L2), and (L3), the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . . , 107-P extending laterally in the first direction (D1) 109, may be formed within different vertical layers within each level. For example, the plurality of horizontally oriented access lines 107-1, 107-2, . . . , 107-P, extending in the first direction (D1) 109, may be formed on a top surface opposing and electrically connected to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . . , 107-P, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digit lines, 103-1, 103-2, . . . , 103-Q, extend in a vertical direction with respect to the substrate 100, e.g., in a third direction (D3) 111. Further, as shown in FIG. 1B, the digit lines, 103-1, 103-2, . . . , 103-Q, in one sub cell array, e.g., sub cell array 101-2 in FIG. 1A, may be spaced apart from each other in the first direction (D1) 109. The digit lines, 103-1, 103-2, . . . , 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digit lines, 103-1, 103-2, . . . , 103-Q, may vertically extend, in the third direction (D3), on sidewalls, adjacent first source/drain regions 121, of respective ones of the plurality of horizontally oriented access devices 130, e.g., transistors, that are vertically stacked. In some embodiments, the plurality of vertically oriented digit lines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, e.g., transistors, in the first level (L1), a sidewall of a first source/drain region 121 of a first one of the horizontally oriented access devices 130, e.g., transistors, in the second level (L2), and a sidewall of a first source/drain region 121 a first one of the horizontally oriented access devices 130, e.g., transistors, in the third level (L3), etc. Similarly, a second one of the vertically extending digit lines, e.g., 103-2, may be adjacent a sidewall to a first source/drain region 121 of a second one of the horizontally oriented access devices 130, e.g., transistors, in the first level (L1), spaced apart from the first one of horizontally oriented access devices 130, e.g., transistors, in the first level (L1) in the first direction (D1) 109. And the second one of the vertically extending digit lines, e.g., 103-2, may be adjacent a sidewall of a first source/drain region 121 of a second one of the laterally oriented access devices 130, e.g., transistors, in the second level (L2), and a sidewall of a first source/drain region 121 of a second one of the horizontally oriented access devices 130, e.g., transistors, in the third level (L3), etc. Embodiments are not limited to a particular number of levels.

The vertically extending digit lines, 103-1, 103-2, . . . , 103-Q, may include a conductive material, such as, for example, one of a doped semiconductor material, a conductive metal nitride, metal, and/or a metal-semiconductor compound. The digit lines, 103-1, 103-2, . . . , 103-Q, may correspond to digit lines (DL) described in connection with FIG. 1A.

As shown in the example embodiment of FIG. 1B, a conductive body contact may be formed extending in the first direction (D1) 109 along an end surface of the horizontally oriented access devices, e.g., transistors, in each level (L1), (L2), and (L3) above the substrate 100. The body contact may be connected to a body e.g., body region, of the horizontally oriented access devices, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p−) semiconductor material. In one embodiment, the body region and the channel region 225 separating the first and the second source/drain regions, 221 and 223, may include a low doped, p-type (e.g., low dopant concentration (p−)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 221 and is in electrical contact with the body contact. Further, as shown in the example embodiment of FIG. 2, an access line, e.g., 207, analogous to the access lines 107-1, 107-2, . . . , 107-P shown in FIG. 1, may disposed on a top surface opposing and connected to a channel region 225, separated therefrom by a gate dielectric material 204. The gate dielectric material 204 may be, for example, a high-k dielectric material, a silicon oxide material, a silicon nitride material, a silicon oxynitride material, etc., or a combination thereof. Embodiments are not so limited. For example, in high-k dielectric material examples the gate dielectric material 204 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . . , 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel region 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 321 and is in contact with the body contact. An insulator material may fill the body contact such that the first source/drain region 221 may not be in electrical contact with channel region 225. Further, as shown in the example embodiment of FIG. 2, an access line, e.g., 207, analogous to the access lines 107-1, 107-2, . . . , 107-P shown in FIG. 1, may disposed all around and connected to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

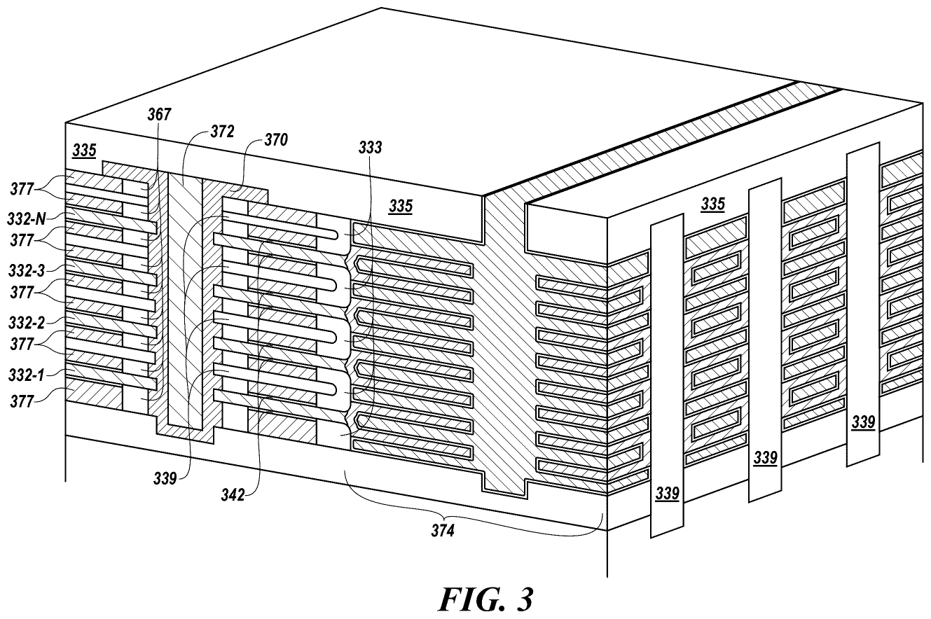

FIG. 3 illustrates a portion of a vertical 3D memory array in accordance with a number of embodiments of the present disclosure. FIG. 3 includes first conductive material 377, an Si material 332, a photolithographic mask material (e.g., mask material) 335, an interlayer dielectric (ILD) fill material 367, a second conductive material 370, a metal material 372, a first dielectric material 339, a second dielectric material 333, a second interlayer dielectric material 342, and a plurality of storage nodes (e.g., capacitors) 374.

FIG. 3 illustrates a portion of a vertical 3D memory array that is formed in accordance with the process described in FIGS. 4-13, as is further described herein. The 3D memory array can include an array of vertically stacked memory cells having a plurality of levels. Each level of the plurality of levels can include horizontally oriented access devices and storage nodes.

Each storage node can include horizontally oriented access devices having first source/drain regions and second source/drain regions separated by channel regions, and gates on a gate dielectric material. The array can further comprise horizontally oriented access lines forming the gates to the horizontally oriented access devices. The horizontally oriented access lines can be gate all around (GAA) structures. The storage nodes can further include horizontally oriented storage nodes electrically connected to the second source/drain regions of the horizontally oriented access devices.

The horizontal access devices of the vertical 3D memory array can include the second dielectric material 333, the first dielectric material 377, a first dielectric material 339, and ILD fill material 367. The access devices can be connected to the plurality of storage nodes 374. In some embodiments, the plurality of storage nodes 374 can be double-sided capacitors. The access devices can be used to transfer current between the metal material 372 and the plurality of storage nodes 374.

Further included in the vertical 3D memory array can be epitaxially formed vertical digit lines connected to the first source/drain regions of the horizontally oriented access devices. Devices and methods of forming the epitaxially grown vertical digit lines are further described herein.

FIG. 4 is a cross-sectional view, at one stage of a semiconductor fabrication process, for digit line formation in vertical three-dimensional (3D) memory, such as illustrated in FIGS. 1-3, and in accordance with a number of embodiments of the present disclosure.

In the example embodiment shown in the example of FIG. 4, the method comprises forming alternating layers of a silicon germanium (SiGe) material, 430-1, 430-2, . . . , 430-N (collectively referred to as silicon germanium (SiGe) 430), and a silicon (Si) material, 432-1, 432-2, . . . , 432-N (collectively referred to as epitaxially grown, single crystalline silicon (Si) material 432), in repeating iterations to form a vertical stack 402 on a working surface of a semiconductor substrate 400. In one embodiment, the silicon germanium (SiGe) 430 can be deposited on a dielectric 431 to have a thickness, e.g., vertical height in the third direction (D3), in a range of five (5) nm to thirty (30) nm. In one embodiment, the silicon material 432 can be deposited to have a thickness (t2), e.g., vertical height, in a range of thirty (30) nanometers (nm) to sixty (60) nm. Embodiments, however, are not limited to these examples. As shown in FIG. 4, a vertical direction 411 is illustrated as a third direction (D3), e.g., z-direction in an x-y-z coordinate system, analogous to the third direction (D3), among first, second, and third directions, shown in FIGS. 1-2.

In some embodiments, the silicon germanium (SiGe), 430-1, 430-2, . . . , 430-N, may be a mix of silicon and germanium. By way of example, and not by way of limitation, the silicon germanium (SiGe) 430 may be grown on a dielectric 431 by way of epitaxial growth. Embodiments are not limited to these examples. In some embodiments, the single crystalline silicon (Si) material, 432-1, 432-2, . . . , 432-N, may comprise a silicon (Si) material in a polycrystalline and/or amorphous state. The single crystalline silicon (Si) material, 432-1, 432-2, . . . , 432-N, may be a low doped, p-type (p-) epitaxially grown, single crystalline silicon (Si) material. The silicon material, 432-1, 432-2, . . . , 432-N, may also be formed by epitaxially growth on the silicon germanium (SiGe) 430. After the epitaxially grown silicon germanium (SiGe) 430 has been formed, the seed is turned to pure silicon. Embodiments, however, are not limited to these examples.

The repeating iterations of alternating silicon germanium (SiGe), 430-1, 430-2, . . . , 430-N layers and epitaxially grown, single crystalline silicon (Si) material, 432-1, 432-2, . . . , 432-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of epitaxially grown silicon germanium (SiGe) and epitaxially grown, single crystalline silicon (Si) material, in repeating iterations to form the vertical stack 402.

The layers may occur in repeating iterations vertically. In the example of FIG. 4, N+1 tiers, numbered 1, 2, 3, N, and N+1 of the repeating iterations are shown. For example, the stack may include: a first silicon germanium (SiGe) 430-1, a first Si material 432-1, a second SiGe material 430-2, a second Si material 432-2, a third SiGe material 430-3, and a Si material 432-3, in further repeating iterations. Embodiments, however, are not limited to this example and more or fewer repeating iterations may be included.

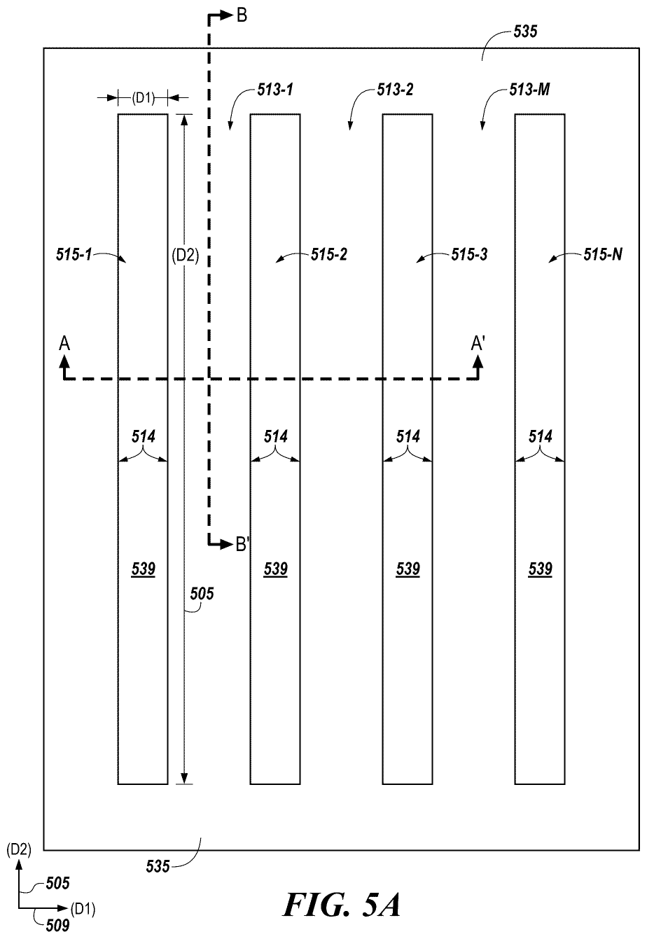

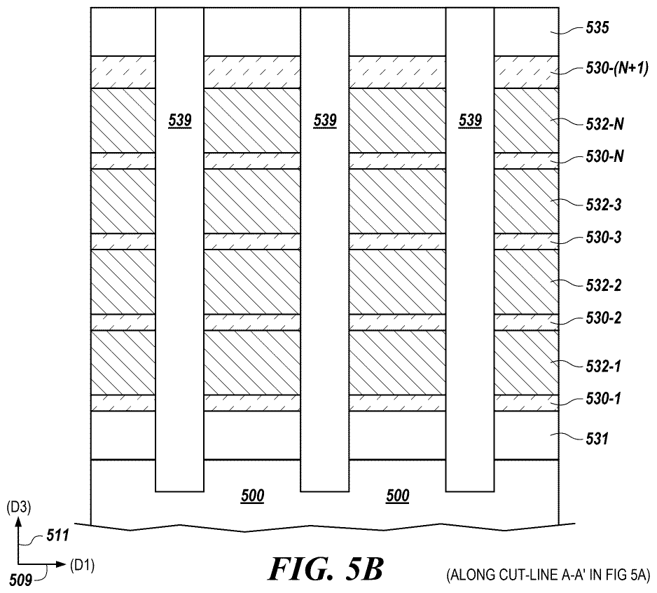

FIG. 5A to 5B illustrate an example method, at one stage of a semiconductor fabrication process, for digit line formation in vertical three-dimensional (3D) memory, such as illustrated in FIGS. 1-3, and in accordance with a number of embodiments of the present disclosure.

FIG. 5A illustrates a top-down view of a semiconductor structure, at a particular point in time, in a semiconductor fabrication process, according to one or more embodiments. In the example embodiment shown in the example of FIG. 5A, the method comprises using an etchant process to form a plurality of first vertical openings 515, having a first horizontal direction (D1) 509 and a second horizontal direction (D2) 505, through the vertical stack to the substrate. In one example, as shown in FIG. 5A, the plurality of first vertical openings 515 are extending predominantly in the second horizontal direction (D2) 505 and may form elongated vertical, columns 513-1, 513-2, . . . , 513-M (collectively and/or independently referred to as 513), with sidewalls 514 in the vertical stack. The plurality of first vertical openings 500 may be formed using photolithographic techniques to pattern a photolithographic mask 535, e.g., to form a hard mask (HM), on the vertical stack prior to etching the plurality of first vertical openings 515. Similar semiconductor process techniques may be used at other points of the semiconductor fabrication process described herein.

FIG. 5B is a cross sectional view, taken along cut-line A-A′ in FIG. 5A, showing another view of the semiconductor structure at a particular time in the semiconductor fabrication process. The cross-sectional view shown in FIG. 5B shows the repeating iterations of alternating layers of silicon germanium (SiGe) 530 and silicon (Si) material 532 on a semiconductor substrate 500 to form the vertical stack, e.g. 402 as shown in FIG. 4.

As shown in FIG. 5B, a plurality of first vertical openings may be formed through the layers within the vertically stacked memory cells to expose vertical sidewalls in the vertical stack and form elongated vertical columns 513 and then filled with a first dielectric material 539. The vertical openings may be formed through the repeating iterations of the silicon germanium (SiGe) 530 and the silicon (Si) material 532.

The vertical openings may be formed to expose vertical sidewalls in the vertical stack. The vertical openings may extend in a second horizontal direction (D2) 505 to form the elongated vertical, columns with first vertical sidewalls in the vertical stack and then filled with the dielectric material 539.

As shown in FIG. 5B, a first dielectric material 539, such as an oxide or other suitable spin on dielectric (SOD), may be deposited in the vertical openings, using a process such as CVD, to fill the vertical openings. First dielectric material 539 may also be formed from a silicon nitride (Si3N4) material. In another example, the first dielectric material 539 may include silicon oxy-nitride (SiOxNy), and/or combinations thereof. Embodiments are not limited to these examples. The plurality of first vertical openings may be formed using photolithographic techniques to pattern a photolithographic mask 535, e.g., to form a hard mask (HM), on the vertical stack prior to etching the plurality of first vertical openings. In one embodiment, hard mask 535 may be deposited over silicon germanium (SiGe) 530. Similar semiconductor process techniques may be used at other points of the semiconductor fabrication process described herein.

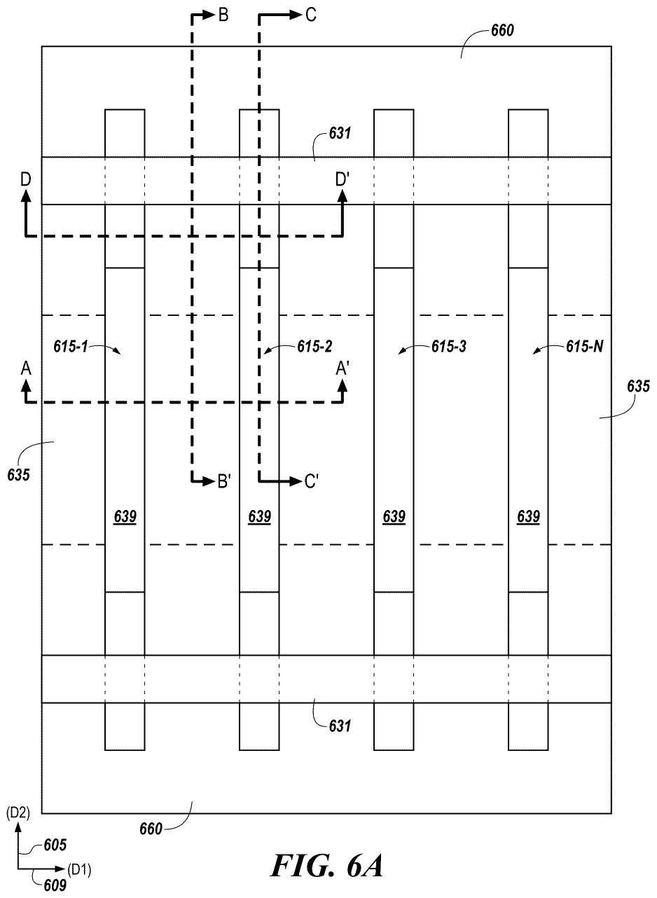

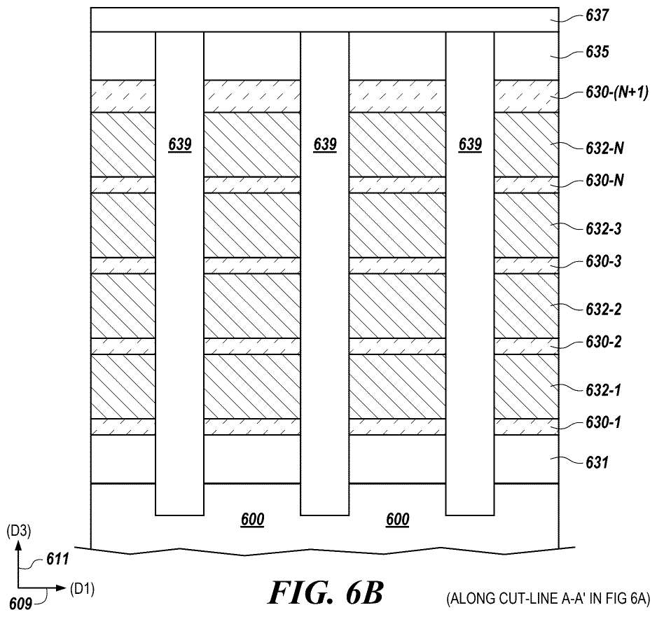

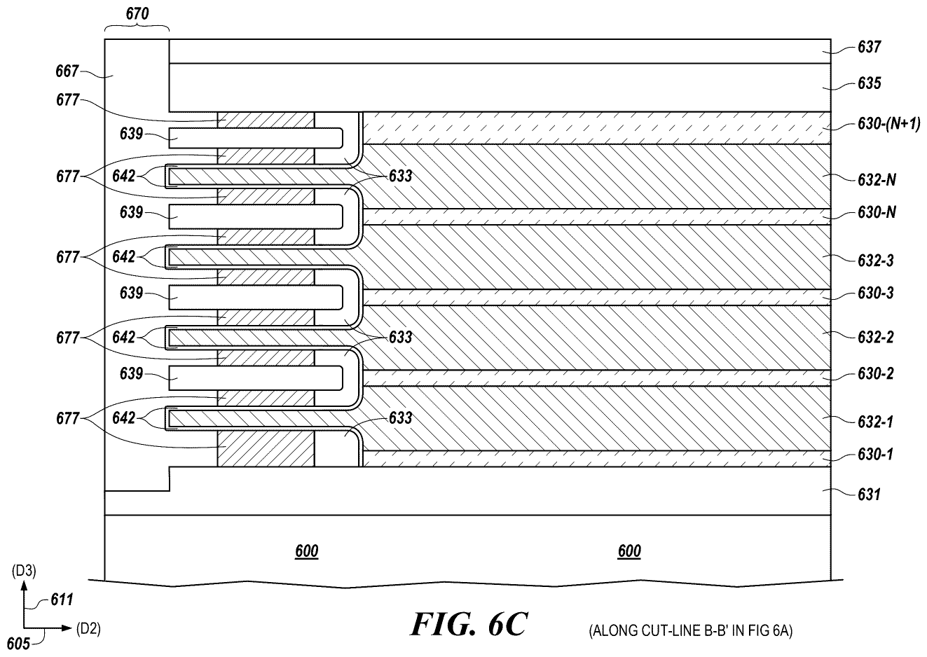

FIGS. 6A to 6C illustrate an example method, at another stage of a semiconductor fabrication process, for digit line formation in vertical three-dimensional (3D) memory in accordance with a number of embodiments of the present disclosure. FIG. 6A illustrates a top-down view of a semiconductor structure, at a particular point in time, in a semiconductor fabrication process, according to one or more embodiments.

In the example embodiment of FIG. 6A, the method comprises using a photolithographic process to pattern a photolithographic mask 635. A plurality of second vertical openings 670 may be formed using the photolithographic mask 635.

For example, the semiconductor fabrication process can include using an etchant process to form a plurality of second vertical openings 670, extending primarily in the first direction (D1) 609 through the vertical stack by patterning and selectively removing the silicon (Si) 632 and silicon germanium (SiGe) 630 material in the plurality of second vertical openings 670 to expose second vertical sidewalls adjacent a first region, e.g., access device region, of the Si and SiGe material 632 and 630.

The semiconductor fabrication process can further include doping a first source/drain region of the Si material 632. That is, the first Si material 632-1, the second Si material 632-2, the third Si material 632-3, and in further repeating iterations, can be doped. For example, a first source/drain region may be formed by gas phase doping a dopant into a side surface portion of the Si material 632. In some embodiments, the source/drain region may be a first source/drain region that will connect to a digit line connection. In one example, gas phase doping may be used to achieve a highly isotropic (e.g., non-directional doping), to form the first source/drain regions for the horizontally oriented access devices. In another example, thermal annealing with doping gas, such as phosphorous (P) may be used with a high energy plasma assist to break the bonding. Embodiments, however, are not so limited and other suitable semiconductor fabrication techniques may be utilized.

FIG. 6B illustrates a cross-sectional view, taken along cut-line A-A′ in FIG. 6A, showing another view of the semiconductor structure at this particular point in one example semiconductor fabrication process of an embodiment of the present disclosure. The cross-sectional view shown in FIG. 6B shows the repeating iterations of alternating layers of the silicon germanium (SiGe) 630 and the silicon (Si) material 632, on a semiconductor substrate 600.

As mentioned in FIG. 6A, the semiconductor fabrication process can include forming second vertical openings 670 (e.g., illustrated in FIG. 6A) through the layers within the vertically stacked memory cells to expose vertical sidewalls in the vertical stack 402 as shown in FIG. 4. The vertical openings 670 can extend predominantly in a first horizontal direction (D1) 609.

As shown in FIG. 6C, the semiconductor fabrication process can further include selectively etching the silicon germanium (SiGe) 630 isotropically to form a plurality of first horizontal openings in the first region separating layers of the Si material 632. The etching process may be a timed, selective etch process which also reduces, e.g., “thins”, a vertical thickness (vt) or vertical height extending in the third direction (D3) 611 of each of the silicon (Si) 632 layers. An etchant may be flowed into the second vertical opening 631 to selectively etch a portion of the epitaxially grown silicon germanium (SiGe) 630 within the stack. As such, the etchant may target the first silicon germanium (SiGe) 630-1, the second silicon germanium (SiGe) 630-2, and the third silicon germanium (SiGe) 630-3 within the stack. The timed, selective etchant process may etch the silicon germanium (SiGe) 630 to entirely remove the SiGe 630 material, extending a first length (L1), from the second vertical openings 670 to form the plurality of first horizontal openings 673. As a result of the etchant process, the vertical thickness (e.g., in the third direction (D3)) of the layers of the Si material 632 occurs.

The selective etchant process may comprise a selective etch chemistry of phosphoric acid (H3PO4) or hydrogen fluoride (HF) and/or dissolving the silicon germanium (SiGe) 630 using a selective solvent, among other possible etch chemistries or solvents. Alternatively, or in addition, a selective etch to remove the silicon germanium (SiGe) 630 may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O2) or O2 and sulfur dioxide (SO2) may be utilized. As another example, a dry etch chemistries of O2 or of O2 and nitrogen (N2) may be used to selectively etch the silicon germanium (SiGe) 630.

The silicon germanium (SiGe) 630 has now been selectively etched isotropically to form a plurality of first horizontal openings 673 in the first region separating layers of the Si material 632.

As shown in FIG. 6C, a second dielectric material 633 may be conformally deposited all around first horizontal opening 673. The second dielectric material 633 may be deposited fully around exposed surfaces in the plurality of first horizontal openings 673. The second dielectric material 633 may serve as a liner around the plurality of first horizonal openings 673. The second dielectric material 633 may be flowed into the vertical opening 631 to cover exposed surfaces of the silicon (Si) material where the silicon germanium (SiGe) was removed to form the plurality of first horizontal openings 673 within the stack.

In one embodiment, the second dielectric material 633 may comprise a nitride material. In another embodiment, second dielectric material 633 may comprise a silicon nitride (Si3N4) material (also referred to herein as “SiN”). In another embodiment the second dielectric material 633 may include silicon dioxide (SiO2) material. In another embodiment the second dielectric material 633 may comprise a silicon oxy-carbide (SiOxCy) material, and/or combinations thereof. Embodiments are not limited to these examples.

In one embodiment, the second dielectric material 633 may be conformally deposited all around exposed surfaces in the plurality of first horizontal openings 673 to have a thickness (t1) of approximately 100 to 300 angstroms (Å). Embodiments, however, are not limited to these examples.

In the example embodiment of FIG. 6C, the semiconductor fabrication process can further include depositing another selectively etchable dielectric material, e.g., the first dielectric material 639, to fill the plurality of first horizontal openings 673. For example, a first dielectric material 639, such as an oxide or other suitable spin on dielectric (SOD), is deposited into the plurality of first horizontal openings 673, on the exposed surfaces of the second dielectric material 633, to fill the first horizontal opening 673. The first dielectric material 639 may entirely fill the plurality of first horizontal openings 673. The first dielectric material 639 may be flowed into the vertical openings 631 to fill the vertical openings 631 and to fill the plurality of first horizontal openings 673 within the stack. As such, the first dielectric material 639 may fill the first horizontal openings 673 within the first silicon germanium (SiGe) 630-1, the second silicon germanium (SiGe) 630-2, and the third silicon germanium (SiGe) 630-3 within the stack.

The semiconductor fabrication process can further include selectively etching the second dielectric material 633 a second length (L2) from the second vertical openings 670 within the plurality of first horizontal openings 673. An etchant may be flowed into the second vertical opening 670 to selectively etch a portion of the second dielectric material 633 the second length (L2) from the second vertical openings 670 within the stack. As such, the etchant may target the second dielectric material 633 within the stack. The selective etchant process may etch the second dielectric material 633 the second length L2. Any selective etch chemistry described herein or otherwise may be utilized for such a selective etchant process.

FIG. 6C illustrates a cross-sectional view, taken along cut-line B-B′ in FIG. 6A, showing another view of the semiconductor structure at this particular point in one example semiconductor fabrication process of an embodiment of the present disclosure. The cross-sectional view shown in FIG. 6C is illustrated extending in the second horizontal direction (D2) 605, left and right in the plane of the drawing sheet, along an axis of the repeating iterations of alternating layers of continuous second horizontal openings 643 and Si material 632.

In FIG. 6C, first dielectric material 639 is shown spaced vertically, and extending along the first horizontal direction (D1) 609, extending into and out from the plane of the drawings sheet, for a three-dimensional array of vertically oriented memory cells. At the left end of the drawing sheet is shown the repeating iterations of alternating layers of the first dielectric material 639.

A first conductive material 667 may be deposited in the second vertical openings 670 to fill the first horizontal openings 673. The first conductive material 667 can be formed on a gate dielectric material 642.

As such, the semiconductor fabrication process can further include first conformally depositing the gate dielectric material 642 to form the gate dielectric material on exposed surfaces of the reduced vertical thickness (vt) of the Si material 632. For example, a gate dielectric material 642 may be formed on exposed surfaces of the Si material 632 to form horizontal access devices. In some embodiments the gate dielectric material may be an oxide material 642. In other embodiments the gate dielectric material 642 may be a high dielectric constant (K) composite material (high-K dielectric material) having a dielectric constant (K) of nine (9), or greater in value. Embodiments are not so limited. The gate dielectric material 642 may be conformally deposited fully around every surface of the Si material 632 to form gate all around (GAA) gate structures, at the channels of the access device regions.

The gate dielectric material 642 may be deposited on exposed surfaces of the Si material 632 using an atomic layer deposition. In some embodiments the gate dielectric material may be an oxide material. The oxide material, or other high-K dielectric material 642 may be selectively deposited on exposed surfaces of the Si material 632 using atomic layer deposition. A thermal oxidation process may be used to densify the ALD deposited dielectric material 642. The thermal oxidation process involves forming oxide material from a hybrid oxide material. The hybrid oxide material may combine a low temperature oxide material and a high temperature oxide material.

In the semiconductor fabrication process, a first conductive material 667 may be deposited on the gate dielectric material 642. The first conductive material 667 may be deposited around the Si material 632 such that the first conductive material 667 may have a top portion above the Si material 632 and a bottom portion below the Si material 632 to form gate all around (GAA) gate structures, at the channels of the access device regions. The first conductive material 667 may be conformally deposited into vertical openings 670 and fill the continuous second horizontal openings 643 up to the unetched portions of the oxide material 642, the first dielectric material 639, and the second dielectric material 633. The first conductive material 667 may be conformally deposited using a chemical vapor deposition (CVD) process, plasma enhanced CVD (PECVD), atomic layer deposition (ALD), or other suitable deposition process.

In some embodiments, the first conductive material 667 may comprise one or more of a doped semiconductor (e.g., doped silicon, doped germanium, etc., a conductive metal nitride, e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc.), and/or some other combination thereof. The first conductive material 667 entwined with the gate dielectric material may form horizontally oriented access lines opposing a channel region of the epitaxially grown, single crystalline silicon (Si) material (which also may be referred to a word lines).

As shown in FIG. 6C, the first conductive material 667 can be recessed to the channel regions. For example, the first conductive material 667, formed on the gate dielectric material 642, may be recessed and etched away from the third vertical opening 670. In some embodiments, the first conductive material 667 may be etched using an atomic layer etching (ALE) process. In some embodiments, the first conductive material 667 may be etched using an isotropic etch process. The first conductive material 667 may be selectively etched leaving the oxide material 642 covering the Si material 632 and the first dielectric material 639 intact. The first conductive material 667 may be selectively etched in the second direction, in the continuous second horizontal openings, a third distance (DIST 3) in a range of twenty (20) to fifty (50) nanometers (nm) back from the third vertical opening 670. The first conductive material 667 may be selectively etched around the Si material 632 back into the continuous second horizontal openings extending in the first horizontal direction.

The first conductive material 667 may be deposited fully around every surface of the Si material 632 on the gate dielectric material 642, to form gate all around (GAA) gate structures, at the channels of the access device regions. The first conductive material 667 may fill the spaces adjacent the bridged Si material 632. Thus, the Si material 632 may be surrounded by first conductive material 667 formed on the gate dielectric material 642.

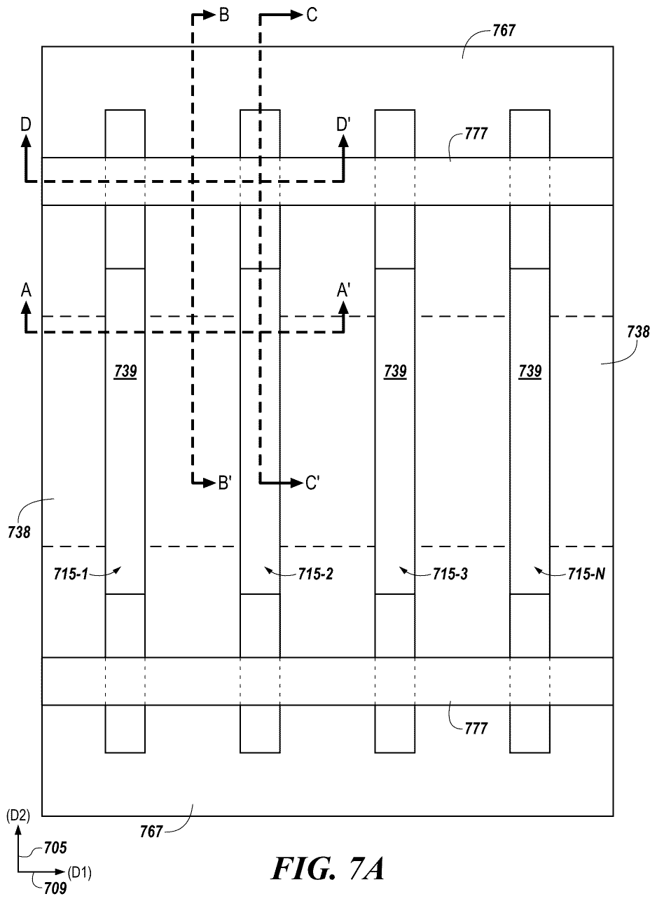

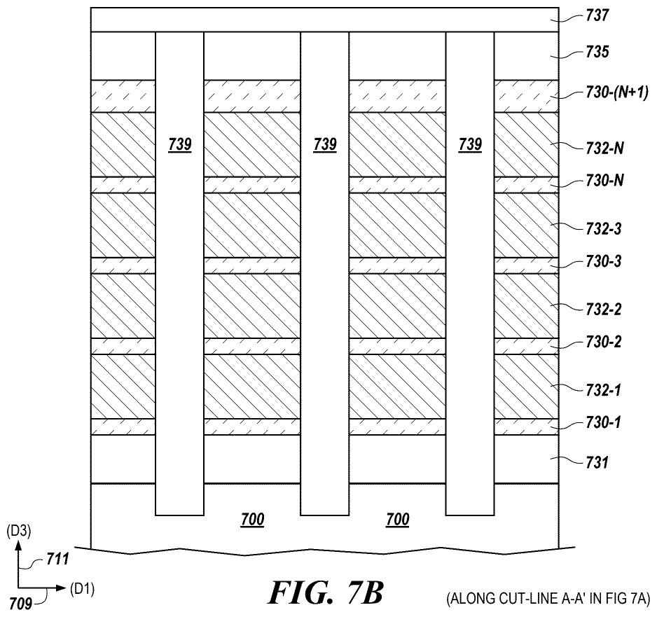

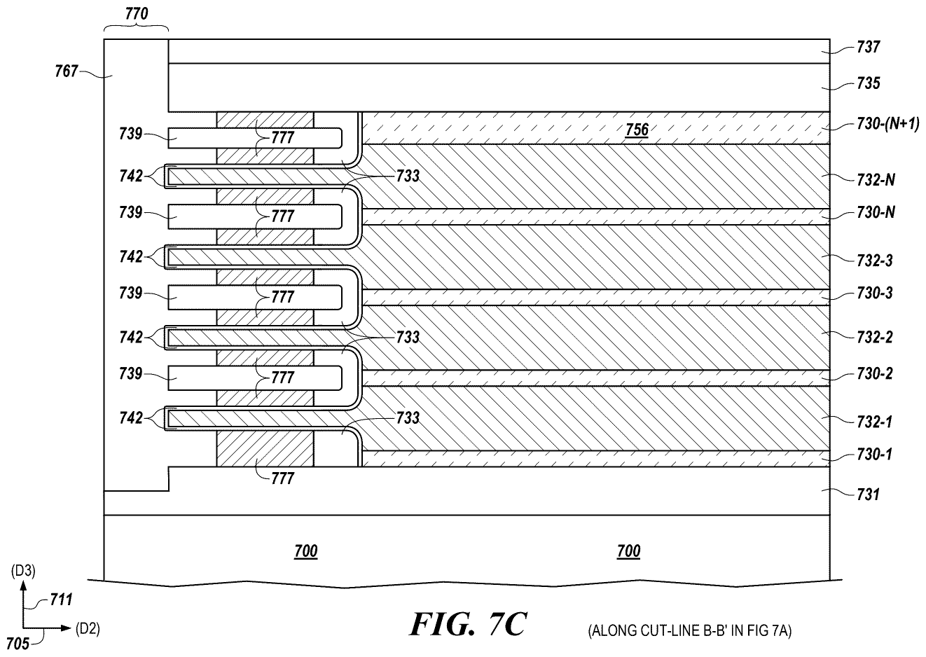

FIGS. 7A to 7C illustrate an example method, at another stage of a semiconductor fabrication process, for digit line formation in vertical three-dimensional (3D) memory, such as illustrated in FIGS. 1-3, and in accordance with a number of embodiments of the present disclosure. FIG. 7A illustrates a top-down view of a semiconductor structure, at a particular point in time, in a semiconductor fabrication process, according to one or more embodiments.

In the example embodiment of FIG. 7A, the second vertical openings may be filled with another selectively etchable dielectric material 767 (as shown in FIG. 7C). In some examples, the selectively etchable dielectric material 767 can be a Nitride cap. The dielectric material 767 can include a thickness greater than a threshold thickness. For example, the threshold thickness can be 90 nanometers (nm), and the thickness of the dielectric material 767 can be 100 nm, although examples of the disclosure are not so limited. The thickness can be utilized to fill interstices gaps between tiers of the stack. The thickness of the Nitride cap can help to control the thickness between the enlarged epitaxially grow Si material contacts, as is further described herein.

In some embodiments the selectively etchable dielectric material may be the same dielectric material as the second dielectric material 633 shown in FIG. 6C. In the example embodiment of FIG. 7A another photolithographic mask may be used to form a third vertical opening 751. The third vertical opening 751 is formed using a photolithographic etchant process through the vertical stack and extending predominantly in the first horizontal direction (D1) 709.

FIG. 7B illustrates a cross-sectional view, taken along cut-line A-A′ in FIG. 7A, showing another view of the semiconductor structure at this particular point in one example semiconductor fabrication process of an embodiment of the present disclosure.

As shown in FIG. 7B, a vertical direction 711 is illustrated as a third direction (D3), e.g., z-direction in an x-y-z coordinate system, analogous to the third direction (D3) 711, among first, second, and third directions, shown in FIGS. 1-3. The plane of the drawing sheet, extending right and left, is in a first direction (D1) 709.

In the example embodiment of FIG. 7B, the first electrodes 761, e.g., bottom electrodes to be connected to source/drain regions of horizontal access devices, and second electrodes 756 are illustrated separated by a cell dielectric material 763 extending into and out of the plane of the drawing sheet in second direction (D2).

FIG. 7C illustrates a cross-sectional view, taken along cut-line B-B′ in FIG. 7A, showing another view of the semiconductor structure at this particular point in one example semiconductor fabrication process of an embodiment of the present disclosure. The cross-sectional view shown in FIG. 7C is illustrated extending in the second horizontal direction (D2) 705, left and right along the plane of the drawing sheet, along an axis of the sacrificial oxide material 738 and Si material 732.

As illustrated in FIG. 7C, an ILD fill material 767 can be deposited in the vertical opening 770. The ILD fill material 767 can be, for example, a capping Nitride material. In some examples, the capping Nitride material can be conformally deposited in the vertical opening 770. In some examples, the capping Nitride material can be deposited in the vertical opening 770 to fill the vertical opening 770.

The capping Nitride material can be deposited to include a thickness greater than a threshold thickness. For example, the thickness of the capping Nitride material can be 100 nanometers (nm). However, embodiments of the present disclosure are not limited to a 100 nm thickness. For example, the thickness of the capping Nitride material can be greater than 100 nm or less than 100 nm. The capping Nitride material can include the thickness greater than the threshold in order to fill in any interstices between tiers by the end of the Silicon material.

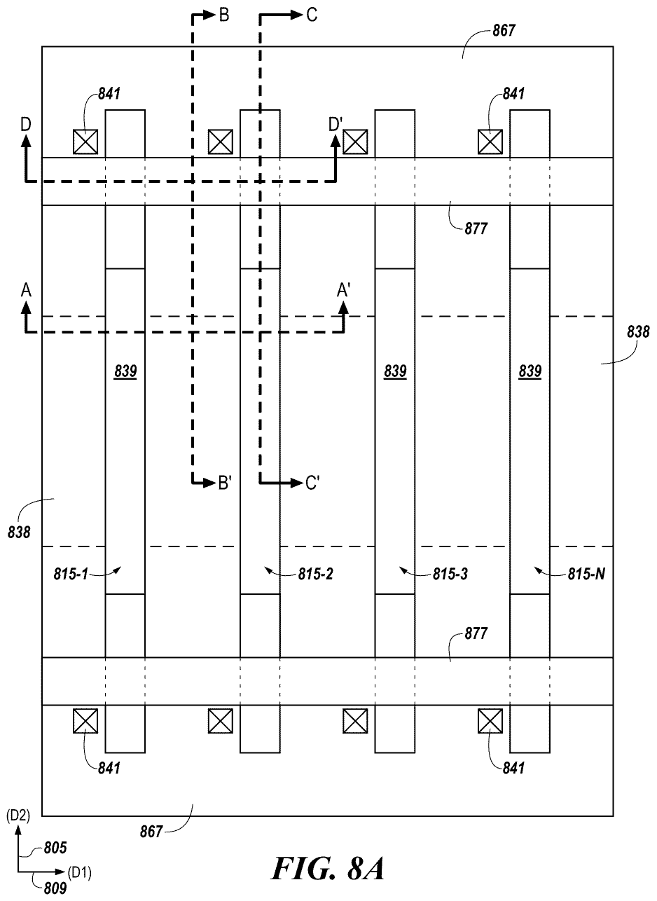

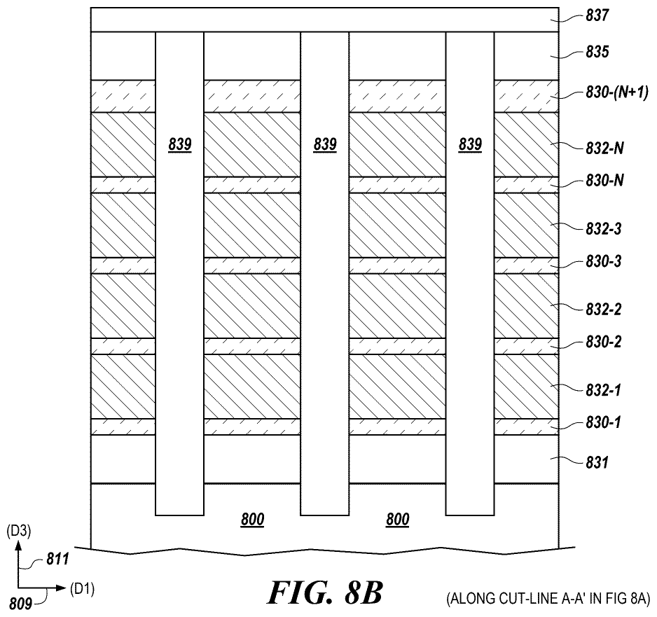

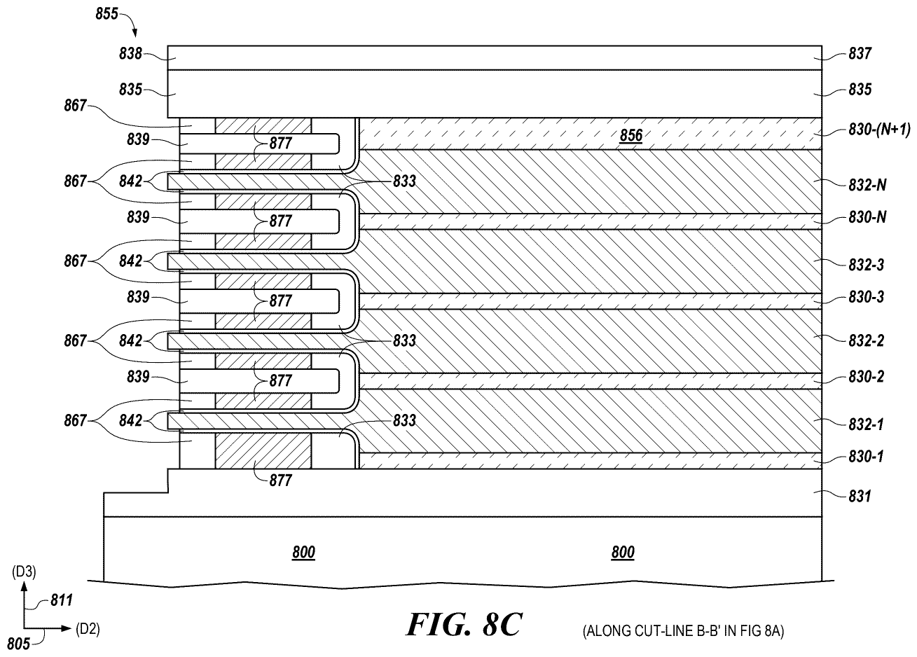

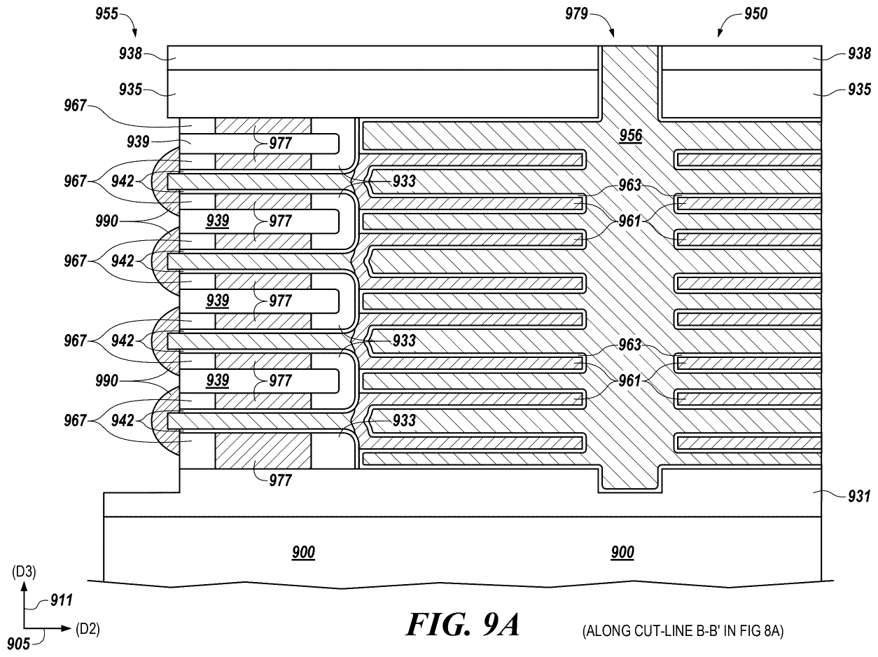

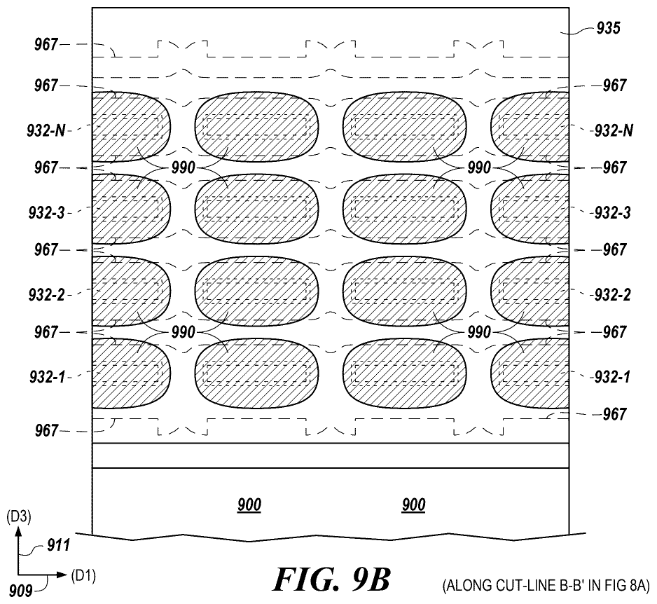

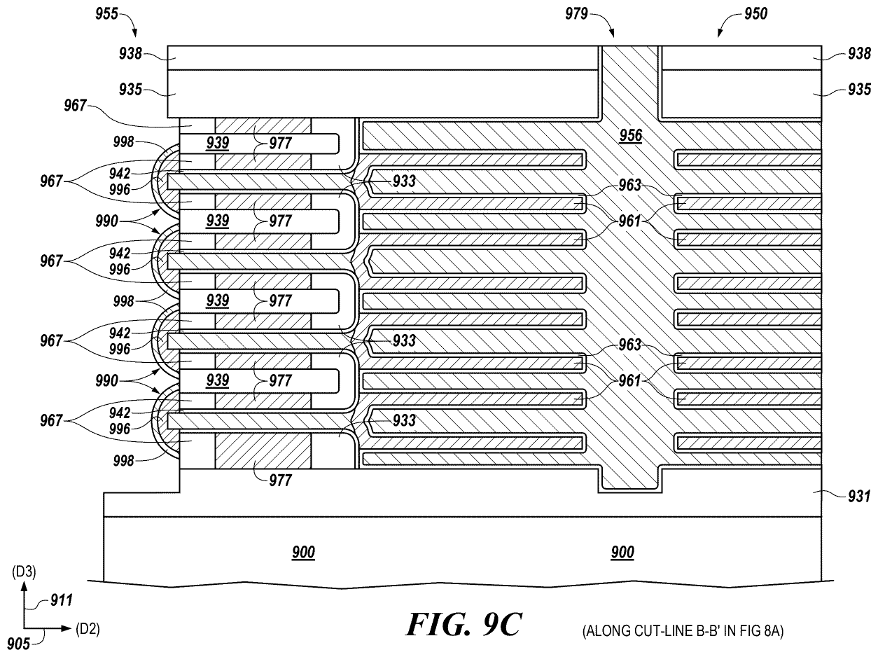

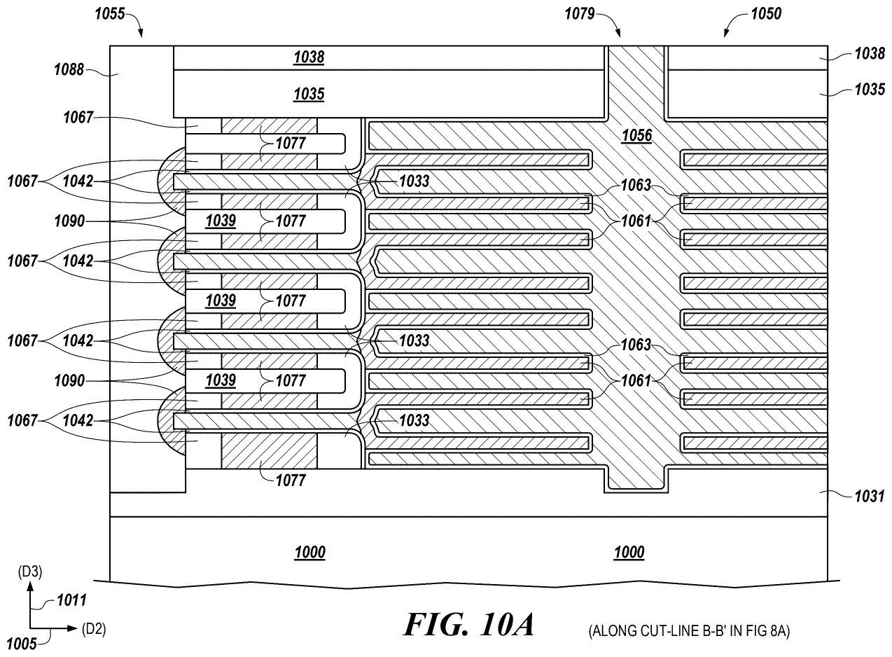

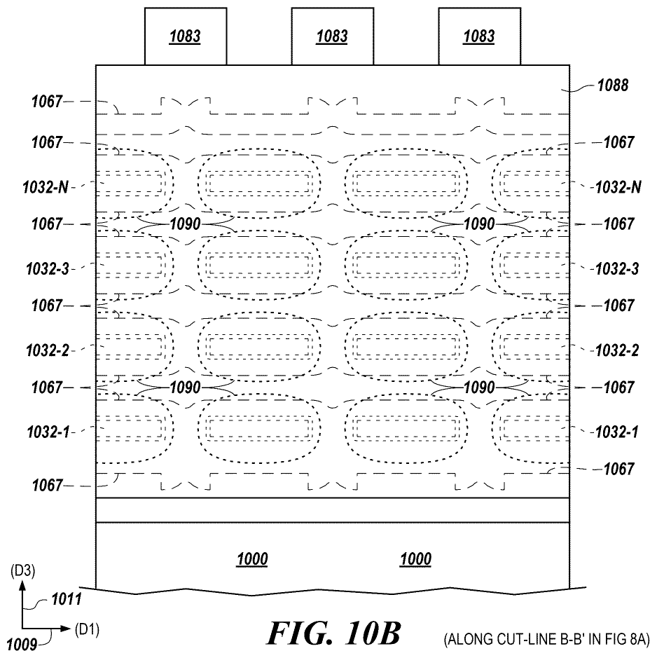

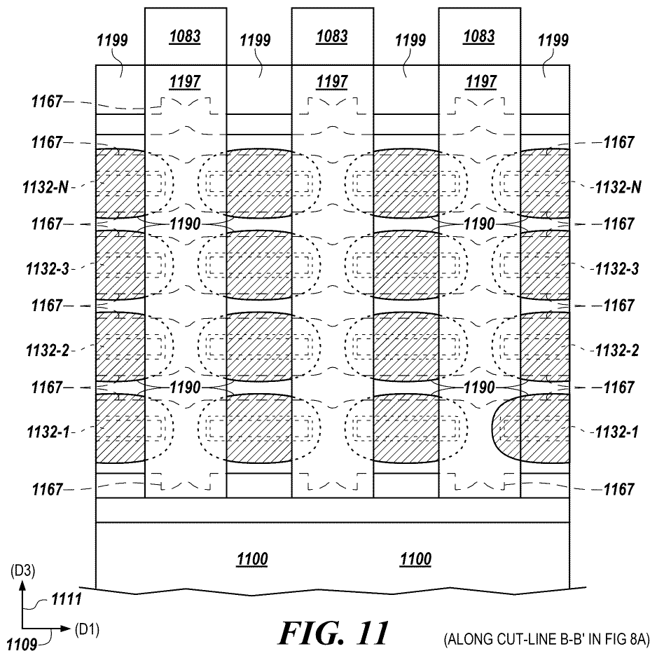

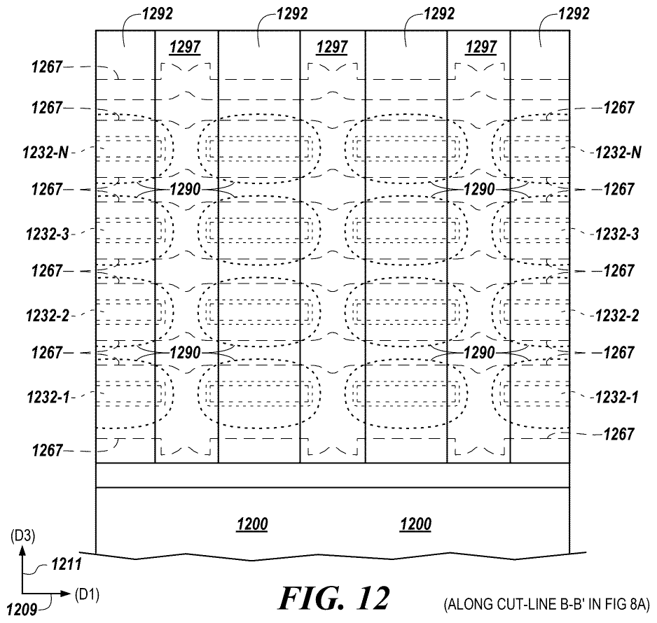

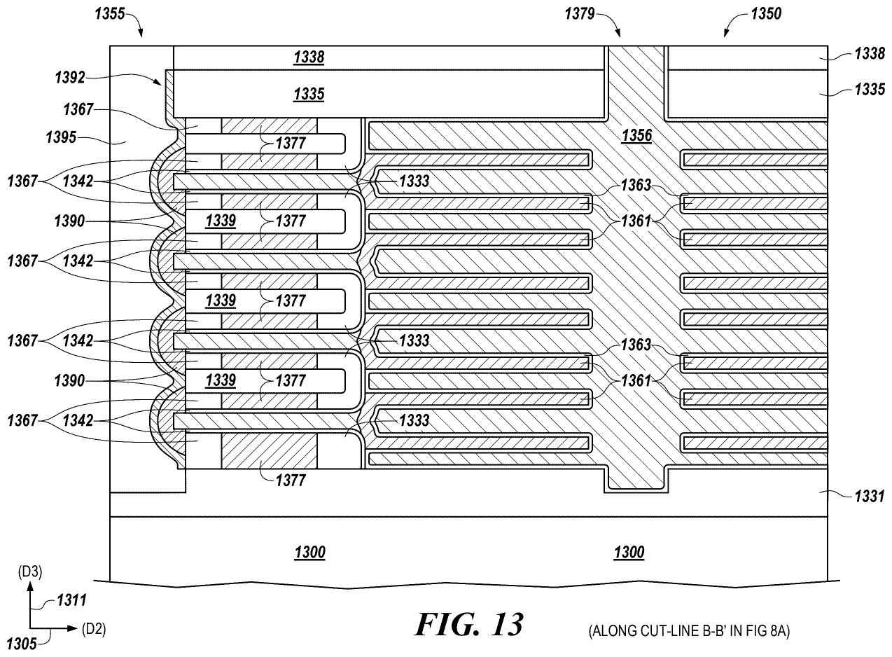

FIGS. 8A to 8C illustrate an example method, at another stage of a semiconductor fabrication process, for digit line formation in vertical three-dimensional (3D) memory, such as illustrated in FIGS. 1-3, and in accordance with a number of embodiments of the present disclosure. FIG. 8A illustrates a top-down view of a semiconductor structure, at a particular point in time, in a semiconductor fabrication process, according to one or more embodiments.

The method in FIG. 8A further illustrates using a photolithographic mask to reopen the second vertical opening 855 adjacent the access device regions. In FIGS. 8A-8C, one or more selective etchant processes may be used to reopen the second vertical opening 851 in the access device region through the vertical stack and extending predominantly in the first horizontal direction (D1) 809. The one or more selective etchant processes reforms the second vertical opening, e.g., a fourth vertical opening 851, to re-expose sidewalls in the repeating iterations of alternating layers of silicon (Si), first dielectric material 839, and dielectric material 867 in the first horizontal openings 863. The dielectric material 867, e.g., same dielectric material as second dielectric material 833, may remain to separate and isolated the recessed first conductive material 877.

FIG. 8B illustrates a cross-sectional view, taken along cut-line A-A′ in FIG. 8A, showing another view of the semiconductor structure at this particular point in one example semiconductor fabrication process of an embodiment of the present disclosure. The cross-sectional view shown in FIG. 8B is away from the plurality of separate, horizontal access lines 877. As shown in FIG. 8B, a vertical direction 811 is illustrated as a third direction (D3), e.g., z-direction in an x-y-z coordinate system, analogous to the third direction (D3) 811, among first, second, and third directions, shown in FIGS. 1-3. The plane of the drawing sheet, extending right and left, is in a first direction (D1) 809.

FIG. 8C illustrates a cross-sectional view, taken along cut-line B-B′ in FIG. 8A, showing another view of the semiconductor structure at this particular point in one example semiconductor fabrication process of an embodiment of the present disclosure. The cross sectional view shown in FIG. 8C is illustrated extending in the second horizontal direction (D2) 805, left and right along the plane of the drawing sheet, along an axis of the repeating iterations of alternating layers of second electrodes 856 along and in which the horizontally oriented access devices.

In FIG. 8C, a neighboring, horizontal access line 877 is illustrated adjacent the second dielectric material 833, with a portion of the first conductive material 877 located above the Si material 832, and a portion of the first conductive material 877 located below the Si material 832 indicating a location set inward from the plane and orientation of the drawing sheet.

The first and the second source/drain regions may be formed by gas phase doping a dopant in a side surface of the Si material 832 from the third horizontal openings to form second source/drain regions horizontally adjacent the channel region. In some embodiments, the dielectric material 867 has been removed from the fourth vertical openings 855, but remains filling the first horizontal openings 863 separating the continuous first conductive material 877, running into and out from the plane of the drawing sheet, up to the unetched portions of the oxide material 839 and fourth vertical opening 855.

Additionally, the semiconductor fabrication process can include three-dimensionally isotropically recessing the surrounding material from the Si material to control a gate to vertical digit line contact to gate spacing. For example, as previously mentioned in FIG. 7C, the capping Nitride material can be conformally deposited in the vertical opening, and the capping Nitride material can be three-dimensionally isotropically recessed using an etching technique. For instance, the capping Nitride material can be recessed in the D3 direction 811, in the D2 direction 805, as well as the D1 direction (e.g., into and out of the page, as oriented in FIG. 8C).

FIGS. 9A to 9C illustrate epitaxially growing Si material to form enlarged epitaxially grown Si material contacts, at another stage of a semiconductor fabrication process, for digit line formation in vertical three-dimensional (3D) memory, in accordance with a number of embodiments of the present disclosure. FIG. 9A illustrates a cross-sectional view, taken along cut-line B-B′ in FIG. 8A, showing another view of the semiconductor structure at this particular point in one example semiconductor fabrication process of an embodiment of the present disclosure. The cross-sectional view in FIG. 9A is illustrated extending in a second horizontal direction (D2) 905 left and right along the plane of the drawing sheet. The method in FIGS. 9A-9C further illustrates storage nodes having been formed, e.g., horizontally oriented capacitor cells, in the third vertical openings. The completed horizontally oriented capacitor cells are shown in this cross-sectional view having first electrodes 961, e.g., bottom cell contact electrodes, cell dielectrics 963, and second electrodes 956, e.g., top, common node electrodes, on a semiconductor substrate 900 to form the vertical stack.

At this stage, the semiconductor fabrication process can include epitaxially growing Si material from the three-dimensionally exposed Si material to form enlarged epitaxially grown Si material contacts 990. In some examples, the epitaxially grown Si material contacts 990 can be a low doped, p-type (p−) epitaxially grown, single crystalline Si material. In some examples, the epitaxially grown Si material contacts 990 can have a gradient doping concentration, as is further described herein.

The epitaxially grown Si material contacts 990 can be grown such that the epitaxially grown Si material contacts 990 can have a cross-sectional dimension greater than an original cross-sectional dimension of the Si material. For example, the epitaxially grown Si material contacts 990 can be grown until they are larger than the Si material the epitaxially grown Si material contacts 990 are grown from. Growing the epitaxially grown Si material contacts 990 can increase a contact area between the epitaxially grown Si material contacts 990 and a digit line while boosting current on without current off degradation, as well as increase contact to gate distance, as compared with previous approaches.

Following epitaxially growing the Si material from the three-dimensionally exposed Si material to form the enlarged epitaxially grown Si material contacts 990, the horizontally oriented storage nodes can be formed. The horizontally oriented storage nodes, e.g., capacitor cells, are illustrated as having been formed in this semiconductor fabrication process and first electrodes 961, e.g., bottom electrodes to be connected to source/drain regions of horizontal access devices, and second electrodes 956, e.g., top electrodes to be connected to a common electrode plane such as a ground plane, separated by cell dielectrics 963, are shown. However, embodiments are not limited to this example. In other embodiments, the first electrodes 961, e.g., bottom electrodes to be connected to source/drain regions of horizontal access devices, and second electrodes 956, e.g., top electrodes to be connected to a common electrode plane such as a ground plane, separated by cell dielectrics 963, may be formed subsequent to forming a first source/drain region, a channel region, and a second source/drain region in a region of the Si material 932, intended for location, e.g., placement formation, of the horizontally oriented access devices.

In the example embodiment of FIG. 9C, the horizontally oriented storage nodes having the first electrodes 961, e.g., bottom electrodes, are connected to second source/drain regions of horizontal access devices. In some embodiments the second source/drain regions may be doped using gas phase doping or other suitable doping techniques before the first electrodes 961 are formed. Second electrodes 956, e.g., top electrodes, connected to a common electrode plane such as a ground plane, are shown formed in a second horizontal opening 951 and separated from the first electrodes 961 by the cell dielectrics 963. The second electrodes 956 may extend in second direction (D2) 905, left and right in the plane of the drawing sheet, a third distance from the third vertical opening, e.g., 951 in FIG. 7B, formed in the vertical stack, and may extend into an interior of the first electrodes 961. In some embodiments, as shown in FIG. 9C, the second electrodes 956 may oppose an interior and exterior surfaces of the first electrodes 961 to form double sided storage nodes, e.g., capacitors, as separated by the cell dielectric along an axis of orientation of the horizontal access devices and horizontal storage nodes of the arrays of vertically stacked memory cells of the three-dimensional (3D) memory.

FIG. 9B illustrates an example method, at another stage of a semiconductor fabrication process, for sculpting Si material for epitaxial digit line growth in vertical three-dimensional (3D) memory in accordance with a number of embodiments of the present disclosure. FIG. 9B illustrates a cross-sectional view, taken along cut-line A-A′ in FIG. 8A, showing another view of the semiconductor structure at this particular point in one example semiconductor fabrication process of an embodiment of the present disclosure. The cross-sectional view shown in FIG. 9B is illustrated extending in the second horizontal direction (D2), left and right along the plane of the drawing sheet, whereas a vertical direction 911 is illustrated as a third direction (D3), e.g., z-direction in an x-y-z coordinate system, analogous to the third direction (D3) 911, among first, second, and third directions, shown in FIGS. 1-3. The plane of the drawing sheet, extending right and left, is in a first direction (D1) 909.

As illustrated in FIG. 9B, the epitaxially grown Si material contacts 990 can be grown a particular amount such that the epitaxially grown Si material contacts 990 are electrically isolated from each other. For example, the epitaxially grown Si material contacts 990 can be grown a particular amount such that the cross-sections of the epitaxially grown Si material contacts 990 are larger than the Si material from which the epitaxially grown Si material contacts 990 are grown, but they do not contact each other in the horizontal D1 direction 909 or in the vertical D3 direction 911.

FIG. 9C illustrates an example method, at another stage of a semiconductor fabrication process, for digit line formation in vertical three-dimensional (3D) memory in accordance with a number of embodiments of the present disclosure. FIG. 9C illustrates a cross-sectional view, again taken along cut-line B-B′ in FIG. 8A, showing another view of the semiconductor structure at this particular point in one example semiconductor fabrication process of an embodiment of the present disclosure. The cross-sectional view in FIG. 9C is illustrated extending in a second horizontal direction (D2) 905 left and right along the plane of the drawing sheet, along an axis of the repeating iterations of alternating layers of second electrodes 956 along and in which the horizontally oriented access devices and horizontally oriented storage nodes, e.g., capacitor cells, can be formed within the layers of epitaxially grown, single crystalline silicon (Si) material 932.

As previously described in connection with FIG. 9A, the semiconductor fabrication process can include epitaxially growing Si material from the three-dimensionally exposed Si material to form enlarged epitaxially grown Si material contacts 990. In some examples, the epitaxially grown Si material contacts 990 can have a gradient doping concentration. For example, the epitaxially grown Si material contacts 990 can include a doping concentration that increases from the Si material outwards.

In order to achieve the gradient doping concentration for the epitaxially grown Si material contacts 990, the semiconductor fabrication process can include epitaxially growing the Si material by epitaxially growing multiple layers of Si material from the three-dimensionally exposed Si material.

For example, the semiconductor fabrication process can include epitaxially growing a first layer 996 of Si material having a first thickness. The first layer 996 can be epitaxially grown to have a first thickness between 5 nm and 20 nm. The first layer 996 of Si material can have a first doping concentration. For example, the first layer 996 of Si material can be an undoped epitaxially grown Si material.

Additionally, the semiconductor fabrication process can further include epitaxially growing a second layer 998 of Si material having a second thickness. For example, the second layer 998 can have a thickness that is less than the thickness of the first layer 996 and can be utilized to control a gate to vertical digit line contact spacing distance. The second layer 998 can be epitaxially grown to have a second thickness that can be between 0 nm and 20 nm. The second layer 998 of Si material can have a second doping concentration that is different from the first doping concentration of the first layer 996. For example, the second layer 998 can include a doping concentration between 1e¹⁸ cm⁻³ and 5e²¹ cm⁻³. The second layer 998 can be a phosphorus doped epitaxially grown Si material.

FIGS. 10A to 10B illustrate forming a plurality of spaced vertical columns having a plurality of spaced vertical openings therebetween, at another stage of a semiconductor fabrication process, for digit line formation in vertical three-dimensional (3D) memory, in accordance with a number of embodiments of the present disclosure. FIG. 10A illustrates a cross-sectional view of a semiconductor structure, at a particular point in time, in a semiconductor fabrication process, according to one or more embodiments. The cross-sectional view in FIG. 10A is illustrated extending in a second horizontal direction (D2) 1005, left to right in the plane of the drawing sheet.

Following epitaxially growing the enlarged epitaxially grown Si material contacts 1090, the semiconductor fabrication process can include forming a plurality of spaced vertical columns having a plurality of spaced vertical openings therebetween in the vertical opening 1055. The enlarged epitaxially grown Si material contacts 1090 can be eventually located between the plurality of spaced vertical columns, as is further described herein.

To form the plurality of spaced vertical columns, a dielectric material 1088 can be deposited into the vertical opening 1055 to fill the vertical opening 1055. For example, the dielectric material 1088 can fill the vertical opening 1055 up to the top of the stack.

FIG. 10B illustrates a cross-sectional view of a semiconductor structure, at a particular point in time, in a semiconductor fabrication process, according to one or more embodiments. The cross-sectional view in FIG. 10B is illustrated extending in a first horizontal direction (D1) 1009 and a vertical direction (D3) 1011. In the cross-sectional view of FIG. 10B, the dielectric material 1088 is located in the vertical opening 1055.

The semiconductor fabrication process can further include patterning a mask 1083 on a top surface of the vertical stack. For example, a photolithographic mask 1083 can be patterned using photolithographic techniques to form a hard mask on the top of the vertical stack.

FIG. 11 illustrates forming the plurality of spaced vertical openings 1199, at another stage of a semiconductor fabrication process, for digit line formation in vertical three-dimensional (3D) memory, in accordance with a number of embodiments of the present disclosure. The cross-sectional view in FIG. 11 is illustrated extending in a first horizontal direction (D1) 1009 and a vertical direction (D3) 1011. In the cross-sectional view of FIG. 11, the mask 1183 is patterned on top of the vertical stack.

To form the plurality of spaced vertical columns 1197, the semiconductor fabrication process can include selectively removing portions of the dielectric material 1188 in the vertical opening to form the plurality of spaced vertical openings 1199. The plurality of spaced vertical openings 1199 are located between the plurality of spaced vertical columns 1197. For example, an etchant process can be utilized to selectively remove portions of the dielectric material 1188 by etching the portions of the dielectric material 1188 to form the plurality of spaced vertical openings 1199, resulting in the plurality of spaced vertical columns 1197.

The etchant process may comprise a selective etch chemistry of phosphoric acid (H3PO4) or hydrogen fluoride (HF) and/or dissolving the dielectric material 1188 using a selective solvent, among other possible etch chemistries or solvents. Alternatively, or in addition, a selective etch to selectively remove portions of the dielectric material 1188 may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O2) or O2 and sulfur dioxide (SO2) may be utilized. As another example, a dry etch chemistries of O2 or of O2 and nitrogen (N2) may be used.

Selectively removing the portions of the dielectric material 1188 can expose the enlarged epitaxially grown Si material contacts 1190. For example, the enlarged epitaxially grown Si material contacts 1190 can be exposed in the plurality of spaced vertical openings 1199 and be located between the plurality of spaced vertical columns 1197.

FIG. 12 illustrates forming a plurality of spaced, multi-layer vertical digit lines, at another stage of a semiconductor fabrication process, for digit line formation in vertical three-dimensional (3D) memory, in accordance with a number of embodiments of the present disclosure. The cross-sectional view in FIG. 12 is illustrated extending in a first horizontal direction (D1) 1009 and a vertical direction (D3) 1011. In the cross-sectional view of FIG. 12, a conductive material is deposited in the plurality of spaced vertical openings.

Once the plurality of vertical openings are formed, the semiconductor fabrication process can include depositing conductive material between the plurality of spaced vertical columns to form a plurality of spaced, vertical digit lines 1292 that are electrically connected to the first source/drain regions. The conductive material can be deposited in the plurality of spaced vertical openings such that the conductive material forms around the enlarged epitaxially grown Si material contacts 1290 in each of the plurality of spaced vertical openings. The conductive material can be, for example, a titanium or titanium nitride material. The plurality of spaced, vertical digit lines 1292 are separated from each other by the plurality of spaced, vertical columns 1297. The plurality of spaced, vertical digit lines 1292 can be utilized in vertical openings having high aspect ratios, such as 5:1 vertical/horizontal aspect ratio specifications, or even higher.

FIGS. 13A to 13B illustrate forming the plurality of spaced, multi-layer vertical digit lines, at another stage of a semiconductor fabrication process, for digit line formation in vertical three-dimensional (3D) memory, in accordance with a number of embodiments of the present disclosure. The cross-sectional view shown in FIG. 13A is illustrated extending in the second horizontal direction (D2) 805, left and right along the plane of the drawing sheet, along an axis of the repeating iterations of alternating layers of second electrodes 1356. In FIG. 13A, the dielectric material deposited in the vertical opening 1355 has been selectively removed to form a plurality of spaced vertical columns and a plurality of spaced vertical openings located between the plurality of spaced vertical columns.

In some examples, the semiconductor fabrication process can include forming a plurality of multi-layer vertical digit lines. For example, the digit lines can include a first layer 1394 and a second layer 1395, as is further described herein.

The semiconductor fabrication process can include depositing a first layer 1394 of material in the plurality of spaced vertical openings. The first layer 1394 of material can contact the epitaxially grown enlarged Si material contacts 1390. In some examples, the first layer 1394 of material can contact the epitaxially grown enlarged Si material contacts 1390 which can be gradient doped, as previously described in connection with FIG. 9C.

The first layer 1394 can be conformally deposited in the plurality of spaced vertical openings. The first layer 1394 can be conformally deposited using a chemical vapor deposition (CVD) process, plasma enhanced CVD (PECVD), atomic layer deposition (ALD), or other suitable deposition process. In some examples, the first layer 1394 can be a doped polysilicon material.

The second layer 1395 can be then deposited into the plurality of spaced vertical openings. The second layer 1395 can be deposited in the plurality of spaced vertical openings up to the top of the vertical stack and to fill the plurality of spaced vertical openings. In some examples, the second layer 1395 can be a titanium nitride (TiN) material.

Accordingly, digit line formation in vertical 3D memory according to the disclosure can allow for increased utilization of contact junction surface area. Epitaxial growth of Si material to form enlarged Si material contacts can provide a larger surface area for contact junctions between digit lines and source/drain regions as well as increasing a contact to gate distance between the gate and digit lines, improving the current on distribution.

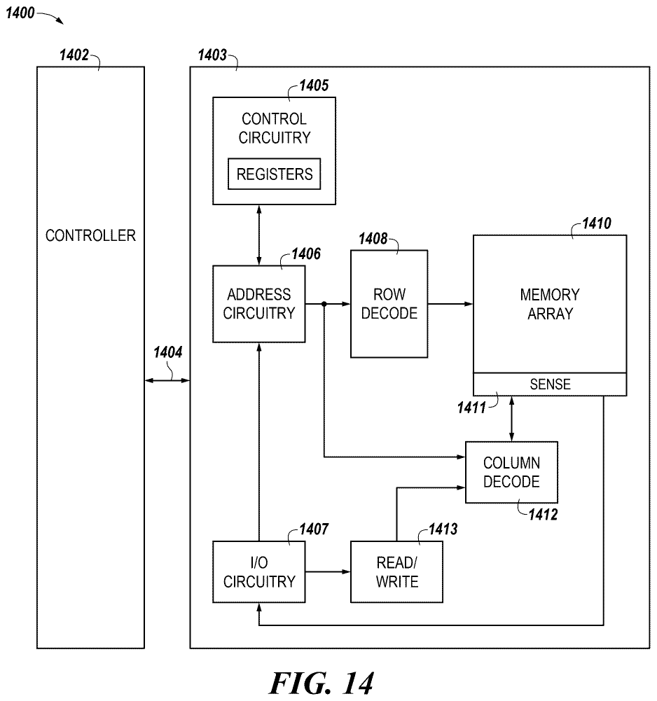

FIG. 14 is a block diagram of an apparatus in the form of a computing system 1400 including a memory device 1403 in accordance with a number of embodiments of the present disclosure. As used herein, a memory device 1403, a memory array 1410, and/or a host 1402, for example, might also be separately considered an “apparatus.” According to embodiments, the memory device 1403 may comprise at least one memory array 1410 with a memory cell formed having a digit line and body contact, according to the embodiments described herein.

In this example, system 1400 includes a host 1402 connected to memory device 1403 via an interface 1404. The computing system 1400 can be a personal laptop computer, a desktop computer, a digital camera, a mobile telephone, a memory card reader, or an Internet-of-Things (IoT) enabled device, among various other types of systems. Host 1402 can include a number of processing resources (e.g., one or more processors, microprocessors, or some other type of controlling circuitry) capable of accessing memory 1403. The system 1400 can include separate integrated circuits, or both the host 1402 and the memory device 1403 can be on the same integrated circuit. For example, the host 1402 may be a system controller of a memory system comprising multiple memory devices 1403, with the system controller 1402 providing access to the respective memory devices 1403 by another processing resource such as a central processing unit (CPU).

In the example shown in FIG. 14, the host 1402 is responsible for executing an operating system (OS) and/or various applications (e.g., processes) that can be loaded thereto (e.g., from memory device 1403 via controller 1402). The OS and/or various applications can be loaded from the memory device 1403 by providing access commands from the host 1402 to the memory device 1403 to access the data comprising the OS and/or the various applications. The host 1402 can also access data utilized by the OS and/or various applications by providing access commands to the memory device 1403 to retrieve said data utilized in the execution of the OS and/or the various applications.

For clarity, the system 1400 has been simplified to focus on features with particular relevance to the present disclosure. The memory array 1410 can be a DRAM array comprising at least one memory cell having a digit line and body contact formed according to the techniques described herein. For example, the memory array 1410 can be an unshielded DL 4F2 array such as a 3D-DRAM memory array. The array 1410 can comprise memory cells arranged in rows connected by word lines (which may be referred to herein as access lines or select lines) and columns connected by digit lines (which may be referred to herein as sense lines or data lines). Although a single array 1410 is shown in FIG. 14, embodiments are not so limited. For instance, memory device 1403 may include a number of arrays 1410 (e.g., a number of banks of DRAM cells).

The memory device 1403 includes address circuitry 1406 to latch address signals provided over an interface 1404. The interface can include, for example, a physical interface employing a suitable protocol (e.g., a data bus, an address bus, and a command bus, or a combined data/address/command bus). Such protocol may be custom or proprietary, or the interface 1404 may employ a standardized protocol, such as Peripheral Component Interconnect Express (PCIe), Gen-Z, CCIX, or the like. Address signals are received and decoded by a row decoder 1408 and a column decoder 1412 to access the memory array 1410. Data can be read from memory array 1410 by sensing voltage and/or current changes on the sense lines using sensing circuitry 1411. The sensing circuitry 1411 can comprise, for example, sense amplifiers that can read and latch a page (e.g., row) of data from the memory array 1410. The I/O circuitry 1407 can be used for bi-directional data communication with the host 1402 over the interface 1404. The read/write circuitry 1413 is used to write data to the memory array 1410 or read data from the memory array 1410. As an example, the circuitry 1413 can comprise various drivers, latch circuitry, etc.

Control circuitry 1405 decodes signals provided by the host 1402. The signals can be commands provided by the host 1402. These signals can include chip enable signals, write enable signals, and address latch signals that are used to control operations performed on the memory array 1410, including data read operations, data write operations, and data erase operations. In various embodiments, the control circuitry 1405 is responsible for executing instructions from the host 1402. The control circuitry 1405 can comprise a state machine, a sequencer, and/or some other type of control circuitry, which may be implemented in the form of hardware, firmware, or software, or any combination of the three. In some examples, the host 1402 can be a controller external to the memory device 1403. For example, the host 1402 can be a memory controller which is connected to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures.

Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “connected” may include electrically connected, directly connected, and/or directly connected with no intervening elements (e.g., by direct physical contact), indirectly connected and/or connected with intervening elements, or wirelessly connected. The term connected may further include two or more elements that co-operate or interact with each other (e.g., as in a cause and effect relationship). An element connected between two elements can be between the two elements and connected to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used.

Therefore, the scope of various embodiments of the present disclosure should be determined with reference to the appended claims, along with the full range of equivalents to which such claims are entitled.

What is claimed is:

1. A method for forming three-dimensional (3D) memory, comprising:
forming a vertical stack having alternating layers of silicon germanium (SiGe) material and silicon (Si) material from a substrate, the vertical stack having vertically stacked memory cells having horizontally oriented access devices and horizontally oriented storage nodes, the horizontally oriented access devices having gates formed horizontally at a different level from each other, channel regions, first source/drain regions, and second source/drain regions separated by the channel regions;
forming a first vertical opening through the vertical stack and extending predominantly in a first horizontal direction to expose first vertical sidewalls in the stack;
three-dimensionally recessing surrounding material from the Si material in the exposed first vertical sidewalls to create three dimensionally exposed surfaces on the Si material;
epitaxially growing Si material from the three-dimensionally exposed Si material to form enlarged epitaxially grown Si material contacts having a cross-sectional dimension greater than an original cross-sectional dimension of the Si material;
forming a plurality of spaced vertical columns between the Si material contacts in the first vertical opening; and
depositing a conductive material between the plurality of spaced vertical columns to form a plurality of spaced, vertical digit lines in the first vertical opening that are electrically connected to the first source/drain regions.

2. The method of claim 1, wherein the method includes epitaxially growing the Si material a particular amount to form the enlarged Si material contacts such that the enlarged Si material contacts are electrically isolated from each other.

3. The method of claim 1, wherein the method includes epitaxially growing the Si material to form the enlarged Si material contacts to have a gradient doping concentration.

4. The method of claim 1, wherein the method includes:
depositing a first dielectric material in the first vertical opening to fill the first vertical opening;
patterning a mask on a top surface of the vertical stack; and
selectively removing portions of the first dielectric material in the first vertical opening to form a plurality of spaced vertical openings between the plurality of spaced vertical columns, wherein selectively removing the portions of the first dielectric material exposes the enlarged Si material contacts in the plurality of spaced vertical openings.

5. The method of claim 4, wherein the method includes depositing the conductive material in the plurality of spaced vertical openings to form the plurality of spaced, vertical digit lines.

6. The method of claim 1, wherein epitaxially growing the Si material includes epitaxially growing multiple layers of Si material from the three-dimensionally exposed Si material.

7. The method of claim 6, wherein epitaxially growing the multiple layers of the Si material includes:
epitaxially growing a first layer of the multiple layers of the Si material to have a first thickness; and
epitaxially growing a second layer of the multiple layers of the Si material to have a second thickness that is less than the first thickness of the first layer to control a gate to vertical digit line contact spacing distance.

8. The method of claim 7, wherein the method includes epitaxially growing the first layer to have a first doping concentration and the second layer to have a second doping concentration that is different from the first doping concentration.

9. The method of claim 7, wherein the method includes:
epitaxially growing the first layer to have a thickness between 1 nanometers (nm) and 20 nm; and
epitaxially growing the second layer to have a thickness between 1 nm and 20 nm.

10. The method of claim 1, wherein forming the horizontally oriented access devices and the horizontally oriented storage nodes at each level of the vertical stack comprises:
forming a plurality of second vertical openings, having a first horizontal direction and a second horizontal direction, through the vertical stack, the second vertical openings extending predominantly in the second horizontal direction to form elongated vertical columns with first vertical sidewalls in the stack, separating memory cells on each level;
doping the first source/drain region of the Si layers at the second vertical opening;
depositing a first dielectric in the plurality of second vertical openings; and
forming a third vertical opening through the vertical stack and extending predominantly in the first horizontal direction to expose second vertical sidewalls in the stack.

11. The method of claim 10, wherein forming the horizontally oriented access devices and the horizontally oriented storage nodes at each level of the vertical stack further comprises:
selectively etching the silicon germanium (SiGe) layers and reducing a vertical thickness of the Si layers to form a plurality of first horizontal openings a first length (L1) from the third vertical opening;
conformally depositing a second dielectric material on exposed surfaces in the plurality of first horizontal openings;
recessing the second dielectric material to expose the first source/drain regions;
depositing the first dielectric material to fill the plurality of first horizontal openings;
selectively etching the second dielectric material from the plurality of first horizontal openings a second length (L2) from the second vertical opening;
forming a gate dielectric material on exposed surfaces of the reduced vertical thickness of the Si layers;
depositing a first conductive material on the Si layers to form gate all around (GAA) structures at the channel regions of the access devices;
recessing the first conductive material to the channel regions; and
capping the first horizontal openings with the second dielectric material.

12. A method for forming three-dimensional (3D) memory, comprising:
forming a vertical stack having alternating layers of silicon germanium (SiGe) material and silicon (Si) material from a substrate, the vertical stack having vertically stacked memory cells having horizontally oriented access devices and horizontally oriented storage nodes, the horizontally oriented access devices having gates formed horizontally at a different level from each other, channel regions, first source/drain regions, and second source/drain regions separated by the channel regions;
forming a first vertical opening through the vertical stack and extending predominantly in a first horizontal direction to expose first vertical sidewalls in the stack;
three-dimensionally recessing surrounding material from the Si material in the exposed first vertical sidewalls to create three dimensionally exposed surfaces on the Si material;
epitaxially growing a gradient doped Si material from the three-dimensionally exposed Si material to form enlarged epitaxially grown Si material contacts having a cross-sectional dimension greater than an original cross-sectional dimension of the Si material;
forming a plurality of spaced vertical columns having a plurality of spaced vertical openings therebetween, wherein the enlarged Si material contacts are located in the plurality of spaced vertical openings; and
depositing a conductive material in the plurality of spaced vertical openings to form a plurality of spaced, vertical digit lines in the first vertical opening that are electrically connected to the first source/drain regions.

13. The method of claim 12, wherein the method includes:
depositing a first dielectric material in the first vertical opening to fill the first vertical opening;
patterning a mask on a top surface of the vertical stack; and
selectively removing portions of the first dielectric material in the first vertical opening to form the plurality of spaced vertical openings between the plurality of spaced vertical columns.

14. The method of claim 13, wherein the method includes selectively removing the portions of the first dielectric material by etching the portions of the first dielectric material.

15. The method of claim 13, wherein depositing the conductive material in the plurality of spaced vertical openings further includes forming a plurality of spaced, multi-layer vertical digit lines that are electrically connected to the first source/drain regions, the plurality of spaced, multi-layer vertical digit lines having a first layer and a second layer, the first layer contacting the epitaxially grown, gradient doped Si material contacts.

16. The method of claim 15, wherein the method includes:
depositing a doped polysilicon as the first layer; and
depositing a titanium nitride (TiN) material as the second layer.

17. The method of claim 12, wherein the method includes three-dimensionally isotropically recessing the surrounding material from the Si material to control a gate to vertical digit line contact to gate spacing.

18. A memory device, comprising:
an array of vertically stacked memory cells having horizontally oriented access devices, and horizontally oriented storage nodes, wherein:
the horizontally oriented access devices include channel regions, first source/drain regions, second source/drain regions separated by the channel regions, and gates on a gate dielectric material; and
the horizontally oriented storage nodes are formed horizontally on the second source/drain regions of the horizontally oriented access devices; and
vertical digit lines having gradient doped enlarged Si material contacts and conductive material deposited in a plurality of vertical openings, wherein the vertical digit lines are connected to the first source/drain regions of the horizontally oriented access devices.

19. The memory device of claim 18, wherein the array comprises horizontally oriented access lines forming the gates to the horizontally oriented access devices.

20. The memory device of claim 19, wherein the horizontally oriented access lines are gate all around (GAA) structures.
